(19) United States
(12) Patent Application Publication
(10) Pub. No.: US 2026/0068029 A1
(43) Pub. Date: Mar. 5, 2026

(54) DUCTING SYSTEM WITH CORE DUCT AND BLEED DUCTS

(71) Applicant: Cisco Technology, Inc., San Jose, CA (US)

(72) Inventors: Joseph F. JACQUES, Austin, TX (US); Joel R. GOERGEN, Soulsbyville, CA (US); Sung W. MOON, Woodbury, MN (US); Albert W. CHAN, San Jose, CA (US); Mark C. NOWELL, Ottawa (CA)

(21) Appl. No.: 19/313,793

(22) Filed: Aug. 28, 2025

Related U.S. Application Data
(60) Provisional application No. 63/688,095, filed on Aug. 28, 2024.

(51) Int. Cl. H05K 1/02

(52) U.S. Cl. CPC H05K 1/0204; H05K 2201/064; H05K 2201/066

(57) ABSTRACT

Vertical line card (VLC) systems are provided. In one aspect, a VLC system includes a vertically-oriented printed circuit board (PCB) defining a lower slot, an upper slot, and a plurality of holes. The VLC system also includes a vertically-oriented integrated circuit (IC) mounted to the PCB. The VLC further includes an IC heat sink having a front fin stack positioned forward of the vertically-oriented PCB. The VLC system also includes fans, cages mounted to the vertically-oriented PCB, and an IC duct. At least one fan is operable to move a first portion of an airflow through the upper slot and to the fan. At least one fan is operable to move a second portion of the airflow across the front fins, through the lower slot, and to the fan. The IC duct isolates the airflow from an airflow flowing through the cages and the holes to another fan of the fans.

### CROSS-REFERENCE TO RELATED APPLICATIONS

This application claims the benefit of co-pending U.S. provisional patent application Ser. No. 63/688,095 filed Aug. 28, 2024. The aforementioned related patent application is herein incorporated by reference in its entirety.

### TECHNICAL FIELD

Embodiments presented in this disclosure generally relate to vertical line card (VLC) systems. More specifically, embodiments disclosed herein relate to VLC systems having enhanced cooling features.

### BACKGROUND

A VLC system has its main printed circuit board (PCB) oriented vertically within a chassis, rather than horizontally. Optical devices and an integrated circuit (IC), such as a switching/routing application-specific circuit (ASIC), can be mounted to the vertically-oriented PCB. During operation, an airflow is directed through the system from the front of the chassis out the back. Cooling the vertically-oriented IC, optical devices, and other components of the VLC system has presented certain challenges.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 is a perspective view of a VLC system according to one or more aspects of the present disclosure.

FIG. 2 is a side cross-sectional view of a front portion of the VLC system of FIG. 1.

FIG. 3 is a front view of the VLC system of FIG. 1.

FIG. 4 is a perspective view of an IC heat sink of the VLC system of FIG. 1.

FIG. 5 is a top view of the VLC system of FIG. 1

FIG. 6 is a side cross-sectional view of the VLC system of FIG. 1.

FIG. 7 is a perspective view of a VLC system according to one or more aspects of the present disclosure.

FIG. 8 is a perspective view of a VLC system according to one or more aspects of the present disclosure.

FIG. 9 is a side cross-sectional view of the VLC system of FIG. 8.

FIG. 10 is a perspective view of a VLC system according to one or more aspects of the present disclosure.

FIG. 11 is a perspective view of a VLC system according to one or more aspects of the present disclosure.

FIG. 12 is a perspective view of an IC heat sink of the VLC system of FIG. 11.

FIG. 13 is a front perspective view of a VLC system according to one or more aspects of the present disclosure.

FIG. 14 is a rear perspective view of the VLC system of FIG. 13.

FIG. 15 is a perspective view of a VLC system according to one or more aspects of the present disclosure.

FIG. 16 is a front perspective view of a VLC system according to one or more aspects of the present disclosure.

FIG. 17 is a rear perspective view of the VLC system of FIG. 16.

FIG. 18 is a perspective view of a vertical line card (VLC) system according to one or more aspects of the present disclosure.

FIG. 19 is a side cross-sectional view of a front portion of the VLC system of FIG. 18.

FIG. 20 is a perspective view of an IC heat sink for a VLC system according to one or more aspects of the present disclosure.

FIG. 21 is a side view of the IC heat sink of FIG. 20.

FIG. 22 is a side view of an IC heat sink for a VLC system according to one or more aspects of the present disclosure.

FIG. 23 is a side view of an IC heat sink for a VLC system according to one or more aspects of the present disclosure.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

In one aspect, a VLC system is provided. The VLC system includes a vertically-oriented printed circuit board (PCB) defining a lower slot, an upper slot, and a plurality of holes. The VLC system also includes a vertically-oriented integrated circuit (IC) mounted to the vertically-oriented PCB. The VLC system further includes an IC heat sink having a vapor chamber and a front fin stack positioned forward of the vertically-oriented PCB. The vapor chamber is operable to transfer heat generated by the IC to front fins of the front fin stack. Also, the VLC system includes a plurality of fans and a cage assembly having cages mounted to the vertically-oriented PCB. In addition, the VLC system includes an IC duct extending at least from the vertically-oriented PCB to at least one fan of the plurality of fans. The at least one fan is operable to move a first portion of an airflow through the upper slot and to the at least one fan, and to move a second portion of the airflow across the front fins, through the lower slot, and to the at least one fan. The IC duct isolates the airflow from an airflow flowing through the cages and through the plurality of holes to at least one other fan of the plurality of fans.

In another aspect, a VLC system is provided. The VLC system includes a vertically-oriented printed circuit board (PCB) defining a lower slot, an upper slot, and a plurality of holes. The VLC system also includes a vertically-oriented integrated circuit (IC) mounted to the vertically-oriented PCB. Further, the VLC system includes an IC heat sink having a front fin stack positioned forward of the vertically-oriented PCB and a rear fin stack positioned rearward of the vertically-oriented PCB. Also, the VLC system includes a cage assembly having cages mounted to the vertically-oriented PCB. Further, the VLC system includes a plurality of fans. In addition, the VLC system includes an IC duct enclosing at least a portion of the rear fin stack and extending at least from the vertically-oriented PCB to at least one fan of the plurality of fans. The at least one fan is operable to move a first portion of an airflow through the upper slot, across rear fins of the rear fin stack, and to the at least one fan, and to move a second portion of the airflow through across front fins of the front fin stack, through the lower slot, across the rear fins of the rear fin stack, and to the at least one fan. The IC duct isolates the airflow from an airflow flowing through the cages and through the plurality of holes to at least one other fan of the plurality of fans.

In yet another aspect, a VLC system is provided. The VLC system includes a vertically-oriented printed circuit board (PCB) defining a lower slot and an upper slot. Also, the VLC system includes a vertically-oriented integrated circuit (IC) mounted to the vertically-oriented PCB. Further, the VLC system includes an IC heat sink having a vapor chamber and a front fin stack positioned forward of the vertically-oriented PCB, the vapor chamber is operable to transfer heat generated by the IC to front fins of the front fin stack. In addition, the VLC system includes a plurality of fans and a cage assembly having cages mounted to the vertically-oriented PCB. Also, the VLC system includes an IC duct having a splitter arranged rearward of the vertically-oriented PCB, the splitter is operable to separate a first portion of an airflow, which moves along the IC duct through the upper slot and to a first set of fans of the plurality of fans, and a second portion of the airflow, which moves along the IC duct across the front fins, through the lower slot, and to a second set of fans of the plurality of fans.

### Example Embodiments

Disclosed herein are VLC systems with enhanced cooling features.

In at least one example, a VLC system includes a vertically-oriented PCB disposed within a chassis. The PCB defines a lower slot, an upper slot, and a plurality of holes (e.g., cage holes and drain holes). A vertically-oriented IC is mounted to the PCB, e.g., to a forward face thereof. In at least one example, the IC is an ASIC, such as a network processing unit (NPU) or switching/routing IC. Cage assemblies having a plurality of cages are also mounted to the PCB, e.g., to the forward face on opposite sides of the IC. The cages are operable to receive optical connectors, which are coupled with the IC by way of the cages and electrical traces on the PCB. The cages can be aligned with the cage holes, and the drain holes can be offset from the cages. The VLC system further includes a plurality of fans operable to move air through the VLC system.

In addition, the VLC system includes an IC heat sink operable to dissipate heat away from the IC. The IC heat sink has a vapor chamber having a vertical portion and a horizontal portion, a front fin stack positioned forward of the PCB, and a rear fin stack positioned rearward of the PCB. The vertical portion is positioned forward of the PCB and is operable to absorb heat generated by the IC. The horizontal portion is connected with the vertical portion and extends, at least in part, rearward of the PCB. In this regard, heat generated by the IC can spread rearward of the PCB by way of the vapor chamber. The VLC system also includes an IC duct extending at least from the vertically-oriented PCB to at least one fan of the plurality of fans. The IC duct may also be referred to as a core duct. The at least one fan is operable to move a first portion of an airflow through the upper slot and to the at least one fan, and to move a second portion of the airflow across the front fins, through the lower slot, and to the at least one fan. In this way, portions of the airflow can flow above and below the IC. The airflows that have traveled through the lower slot and the upper slot can combine rearward of the IC heat sink, or in some examples, these airflows can remain separate (e.g., by way of a splitter that fluidly isolates these two portions). Notably, the IC duct isolates the airflow flowing along the IC duct from an airflow flowing through the cages and through the plurality of holes to at least one other fan of the plurality of fans.

The arrangement of the VLC system, including the arrangement of the lower and upper slots provided by the PCB, the IC heat sink, and the IC duct can provide one or more advantages, benefits, and/or technical effects. For instance, the arrangement of the VLC system advantageously allows for airflow paths above and below the IC to carry heat away from the strategically positioned fins of the IC heat sink, and to fluidly isolate this airflow from other airflows through the VLC system. In at least some aspects, certain sets of fans can be controlled independently of one another so that the mass flow rates of the airflows through the VLC system can be different (or the same). For instance, the airflow flowing along the IC duct can be controlled by a first set of fans and the airflow flowing through the cage assembly can be controlled by a second set of fans, and these sets of fans can be controlled so that the mass flow rates of these airflows are different (or the same). Accordingly, the IC duct provides an airflow dedicated to cooling the IC, and this airflow can be controlled differently from the other airflows through the VLC system. In this way, the IC can be controlled according to its heat load with precision and with reduced fan power consumption.

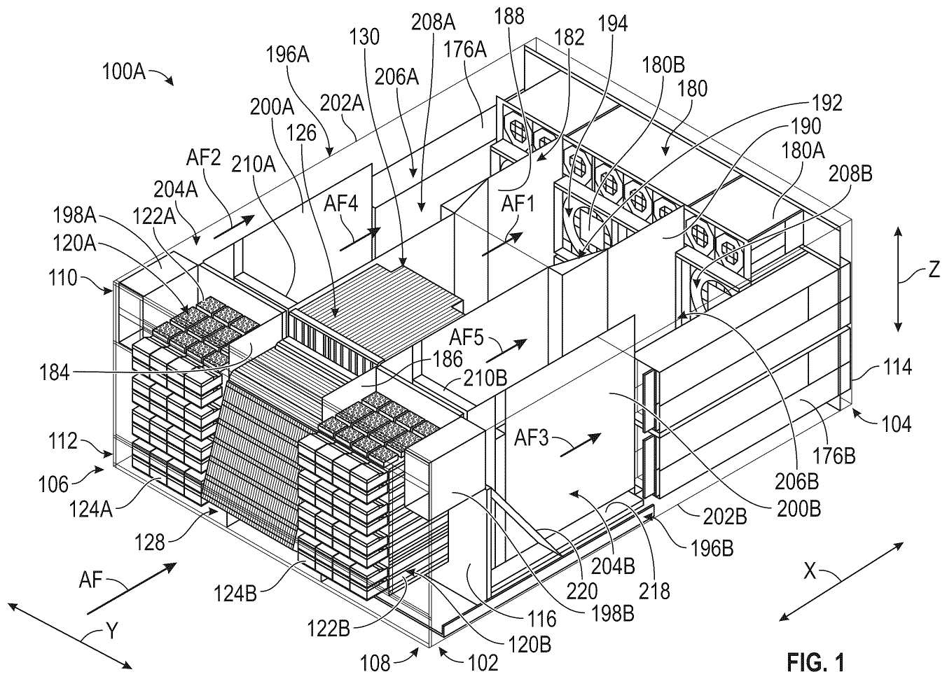

FIG. 1 is a perspective view of a VLC system 100A, according to one or more aspects of the present disclosure. The VLC system 100A can be configured as a router for networking applications, for example. For reference, the VLC system 100A defines an X-direction, a Y-direction, and a Z-direction, which are mutually perpendicular to one another. In at least one example, the X-direction is a longitudinal direction, the Y-direction is a lateral direction, and the Z-direction is a vertical direction. The VLC system 100A extends between a front 102 and a back 104 along the X-direction, between a first side 106 and a second side 108 along the Y-direction, and between a top 110 and a bottom 112 along the Z-direction.

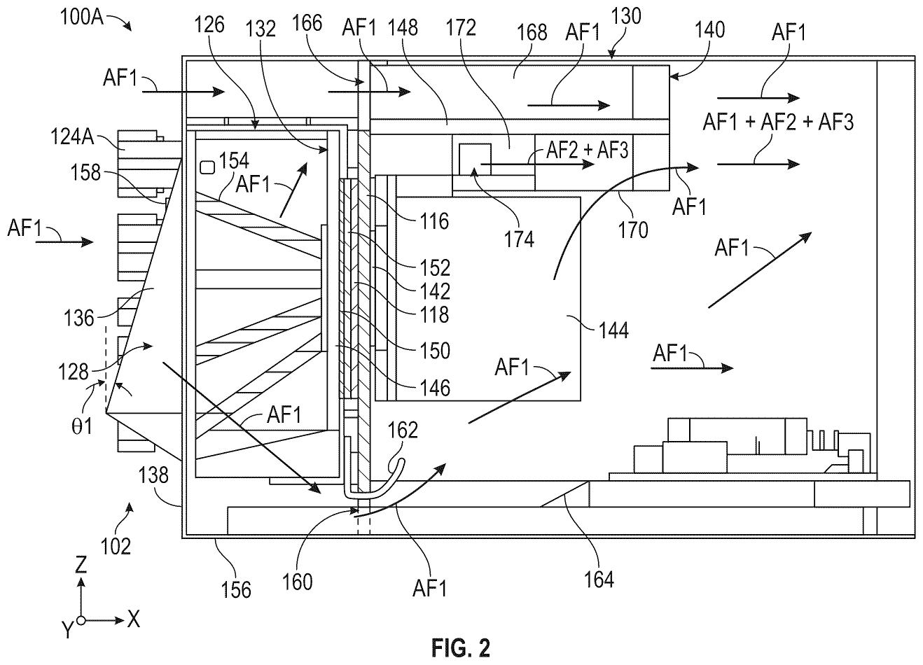

As depicted in FIG. 1, the VLC system 100A includes a chassis 114 that supports and encloses components of the VLC system 100A. In FIG. 1, some portions of the chassis 114 are shown transparent for illustrative purposes. The VLC system 100A includes a vertically-oriented PCB 116. The PCB 116 has a thickness along the X-direction, extends vertically between the top 110 and the bottom 112 of the VLC system 100A, and extends laterally between the first side 106 and the second side 108 along the Y-direction. Stated another way, the PCB 116 extends in a plane perpendicular to the X-direction. A vertically-oriented IC 118 (FIG. 2), is mounted to a forward face of the PCB 116. In at least one example, the IC 118 is an ASIC, such as an NPU or switching/routing IC. Like the PCB 116, the IC 118 extends in a plane perpendicular to the X-direction.

The VLC system 100A also includes at least one cage assembly. In this example, the VLC system 100A includes a first cage assembly 120A and a second cage assembly 120B, which are located generally at the front 102 and are arranged on opposite sides of the IC 118 (FIG. 2). The first cage assembly 120A has a plurality of first cages 122A, and similarly, the second cage assembly 120B has a plurality of second cages 122B. The first cages 122A, or first optical cages, provide ports for receiving the first optical connectors 124A, also called optical modules. In at least one example, the first cages 122A are each arranged as back-to-back 2×1 cages with a riding heat sink. Optical signals can travel via a signal path from the first optical connectors 124A to respective optical-to-electrical converters, which can convert the optical signals to electrical signals. The electrical signals can travel along the signal path to the IC 118 (FIG. 2) for processing, e.g., by way of respective electrical traces disposed on the PCB 116. In addition, electrical signals from the IC 118 can travel the opposite way along the signal path, e.g., by way of the electrical traces to respective electrical-to-optical converters, which can convert the electrical signals to optical signals. The optical signals can travel along the signal path through their respective first cages 122A to their respective first optical connectors 124A.

The second cages 122B can provide ports for receiving second optical connectors 124B. In at least one example, the second cages 122B are each arranged as back-to-back 2×1 cages with a riding heat sink. Optical signals can travel via a signal path from the second optical connectors 124B to respective optical-to-electrical converters, which can convert the optical signals to electrical signals. The electrical signals can travel along the signal path to the IC 118 for processing, e.g., by way of respective electrical traces disposed on the PCB 116. In addition, electrical signals from the IC 118 can travel the opposite way along the signal path, e.g., by way of the electrical traces to respective electrical-to-optical converters, which can convert the electrical signals to optical signals. The optical signals can travel along the signal path through their respective second cages 122B to their respective second optical connectors 124B.

With reference now to FIGS. 1 and 2, FIG. 2 is a side cross-sectional view of a front portion of the VLC system 100A. In one or more examples, the VLC system 100A includes an IC heat sink 126 having a front fin stack 128, a rear fin stack 130, and a vapor chamber 132. The front fin stack 128 is disposed forward of the PCB 116 along the X-direction and between the first and second cage assemblies 120A, 120B along the Y-direction. The front fin stack 128 includes a plurality of front fins 136 that facilitate cooling of the IC 118. In this example, the front fins 136 are trapezoidal fins. However, in other examples, the front fins 136 are canted fins. In yet other examples, the front fins 136 include a combination of trapezoidal and canted fins. In at least one example, at least a portion of the front fins 136 extend forward of a front plate 138 of the chassis 114. In at least one example, the front fin stack 128 is protected by a sloped housing that extends beyond the front plate 138 of the chassis 114. Accordingly, in one or more examples, no perforations or grid is needed.

The rear fin stack 130 is disposed rearward of the PCB 116 along the X-direction. The rear fin stack 130 includes a plurality of rear fins 140 that facilitate cooling of the IC 118 and other components, such as a power module 142 (e.g., a voltage regulator module (VRM)) disposed rearward of the PCB 116. The power module 142 has an associated power module heat sink 144. The power module heat sink 144 is positioned below the rear fin stack 130 along the Z-direction and rearward of the PCB 116 along the X-direction.

The vapor chamber 132 is operable to transfer heat away from the IC 118 and to the front fin stack 128 and the rear fin stack 130. The vapor chamber 132 has a vertical portion 146 and a horizontal portion 148, which are fluidly coupled with one another and arranged in an L-shape. In at least one example, the vertical portion 146 is arranged at a ninety degree (90°) angle with respect to the horizontal portion 148, e.g., as shown in FIG. 2. The vertical portion 146 is parallel with the IC 118 while the horizontal portion 148 is perpendicular with the IC 118. Stated another way, the vertical portion 146 extends in a plane perpendicular to the X-direction while the horizontal portion 148 extends in a plane perpendicular to the Z-direction.

The vapor chamber 132 has a pedestal 150 integrated with the vertical portion 146. The pedestal 150 contacts a thermal interface material (TIM), or TIM 152, arranged between the pedestal 150 and the IC 118. During operation, heat generated by the IC 118 is conducted through the TIM 152 into the pedestal 150 and ultimately to the other portions of the vapor chamber 132. Heat pipes 154 of the front fin stack 128 can be soldered or otherwise attached to the front face of the vertical portion 146 of the vapor chamber 132, e.g., as shown in FIG. 2. In at least one example, the heat pipes 154 can “fan out” or diverge from one another as they extend forward (or toward the front 102) away from the vertical portion 146 along the X-direction. The heat transferred from the IC 118 to the vertical portion 146 can be transferred to the heat pipes 154 and carried by the heat pipes 154 to the front fins 136 of the front fin stack 128. The front fins 136 of the front fin stack 128 can be cooled by an incoming airflow AF. That is, the airflow AF can move the heat away from the front fins 136. Accordingly, the front fin stack 128 provides cooling for the IC 118.

The horizontal portion 148 of the vapor chamber 132 connects with the vertical portion 146, e.g., at a position forward of the PCB 116 along the X-direction. The horizontal portion 148 extends through a notch defined by the PCB 116 and rearward of the PCB 116. During operation, heat generated by the IC 118 can conduct from the vertical portion 146 to the horizontal portion 148, and ultimately to the rear fins 140 of the rear fin stack 130. The airflow AF can move the heat away from the rear fins 140. Accordingly, the rear fin stack 130 also provides cooling for the IC 118, among other components.

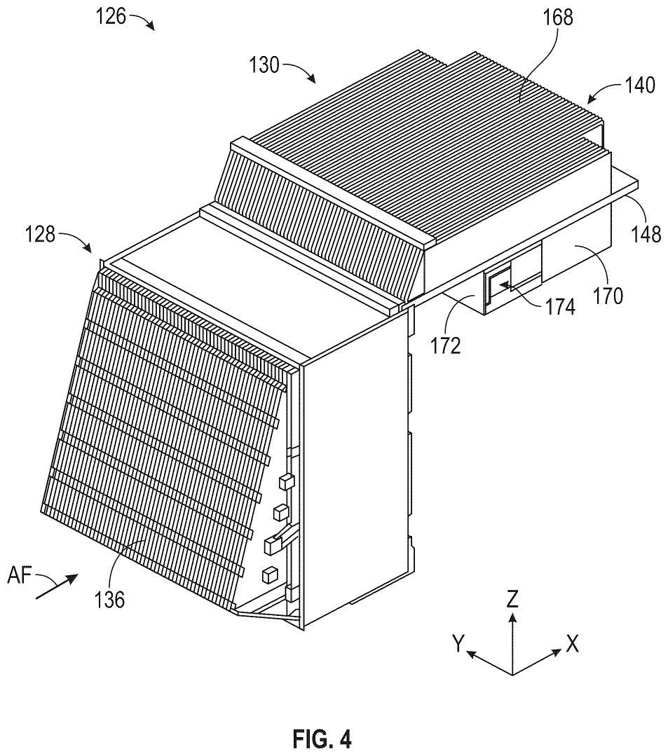

With reference now to FIGS. 2 and 4, FIG. 4 provides a perspective view of the IC heat sink 126. In the depicted example of FIGS. 2 and 4, the front fin stack 128 is arranged so that the front fins 136 have a “rearward lean”. Particularly, in this example, at least some of the front fins 136 are angled with respect to the Z-direction, for at least a portion of the longitudinal length of the front fin stack 128 so that the front fins 136 slope downward (e.g., toward a base plate 156 of the chassis 114) as they extend rearward along the X-direction. As shown in FIG. 2, a front upper face 158 formed by the front fins 136 is slanted at an angle θ1 with respect to the Z-direction. In at least one example, the angle θ1 is between ten and twenty degrees (between 10° and 20°), including the endpoints. In at least one example, the angle θ1 is between fifteen and thirty degrees (between 15° and 30°), including the endpoints. Thus, the lower end of the front upper face 158 is positioned forward of the upper end of the front upper face 158 along the X-direction, and the front fins 136 are sloped accordingly. Advantageously, the front fins 136 are angled to guide incoming airflow AF downward to a lower slot 160 defined by the PCB 116, e.g., as shown in FIG. 2. In this way, the airflow AF can carry heat generated by the IC 118 away from the front fins 136 rearward of the PCB 116.

In one or more examples, a guide vane 162 is arranged at the lower slot 160. The guide vane 162 has a curved face to guide the airflow AF into and through the lower slot 160. In the depicted example of FIG. 2, the guide vane 162 has a convex shape with respect to the lower slot 160. In this regard, the guide vane 162 directs airflow guided downward by the front fins 136 into the lower slot 160 in a smooth and efficient manner, which can reduce pressure losses and provide a more consistent airflow through the lower slot 160. The convex curvature of the guide vane 162 rearward of the PCB 116 can gradually guide the airflow rearward and upward, e.g., so as to be directed at the power module heat sink 144. In this way, the airflow AF that has passed through the lower slot 160 can move through the fins of the power module heat sink 144, which ultimately provides cooling to the power module 142. In at least one example, the guide vane 162 is coupled with, or forms a part of, the vertical portion 146 of the vapor chamber 132.

In one or more examples, the base plate 156 of the chassis 114 includes a ramp 164 positioned rearward of the lower slot 160. The ramp 164 provides an aerodynamic feature that deflects air that has passed through the lower slot 160 upward to flow across vertically-oriented fins of the power module heat sink 144. Accordingly, the ramp 164 can enhance the cooling of the power module 142, especially when used in combination with the guide vane 162. Specifically, the ramp 164 and the guide vane 162 can utilize the Coanda effect to direct the air that has passed through the lower slot 160 across the fins of the power module heat sink 144. The guide vane 162 and the ramp 164 effectively provide a nozzle to direct airflow to the bottom side of the power module heat sink 144.

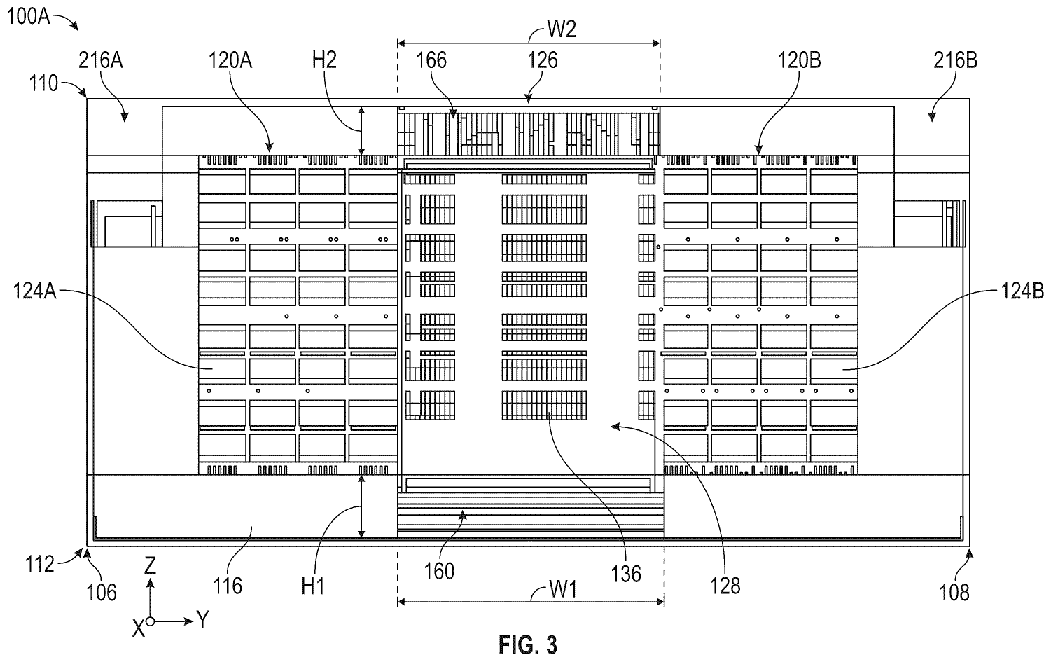

With reference now to FIG. 3, a front view of the VLC system 100A is provided. As depicted in FIG. 3, the PCB 116 defines the lower slot 160 so that the lower slot 160 is positioned vertically below the front fins 136 of the front fin stack 128 along the Z-direction and laterally between the first and second cage assemblies 120A, 120B along the Y-direction. In at least one example, the lower slot 160 is defined by the PCB 116 to have a width W1, as measured along the Y-direction. In at least one example, the width W1 of the lower slot 160 is substantially the same as a width of the front fin stack 128. Also, the lower slot 160 has a height H1 that extends from a lower end of the PCB 116 to a height that is substantially even with the lower end of the first and second cage assemblies 120A, 120B, e.g., as shown in FIG. 3. Advantageously, such a size of the lower slot 160 can reduce the pressure drop of the airflow through the VLC system 100A.

Further, as shown in FIG. 3, the PCB 116 also defines an upper slot 166. The upper slot 166 is positioned vertically above the front fins 136 of the front fin stack 128 along the Z-direction and laterally between the first and second cage assemblies 120A, 120B along the Y-direction. In this regard, the lower slot 160 and the upper slot 166 can be laterally aligned, at least in part, along the Y-direction. Moreover, in at least one example, the upper slot 166 is defined by the PCB 116 to have a width W2, as measured along the Y-direction. In at least one example, the width W2 of the upper slot 166 is substantially the same as the width of the front fin stack 128. Also, the upper slot 166 has a height H2 that extends from an upper end of the PCB 116 to a height that is substantially even with the upper end of the first and second cage assemblies 120A, 120B, e.g., as shown in FIG. 3. Advantageously, such a size of the upper slot 166 can reduce the pressure drop of the airflow through the VLC system 100A. Notably, at least some of the rear fins 140 (i.e., the upper rear fins) are laterally and vertically positioned in communication with the upper slot 166 so that airflow AF is flowable to the rear fins 140 of the rear fin stack 130 unimpeded by the front fins 136 of the front fin stack 128. In this regard, relatively cool air, which has not passed through the front fin stack 128, is flowable directly to the rear fins 140 of the rear fin stack 130, e.g., as shown in FIG. 2. Also, in at least one example, a portion of the air that has passed through the front fin stack 128 passes through the upper slot 166, e.g., as shown in FIG. 2.

Further, in one or more examples, the front fin stack 128 forms the primary electromagnetic interference (EMI) shielding at air intake. At least one example, the front fins 136 are electrically grounded by a conductive bond to a perimeter housing that is part of a front panel assembly, thus eliminating need for a separate EMC shield panel, which would restrict airflow to the VLC system 100A. In at least one example, an upper EMI screen and a lower EMI screen can be provided on the front fins 136 of the front fin stack 128.

Returning to FIGS. 2 and 4, the rear fin stack 130 will now be further described. In this example, the rear fins 140 include upper rear fins 168 and lower rear fins 170. The upper rear fins 168 are positioned above a horizontal portion 148 of a vapor chamber 132 along the Z-direction. The lower rear fins 170 are positioned below the horizontal portion 148 of the vapor chamber 132 along the Z-direction.

In at least one example, as depicted in FIG. 4 but not in FIG. 1 or 2, the upper rear fins 168 are slanted at their forward ends. That is, each one of the upper rear fins 168 is configured so that the lower end of the leading edge of a given one of the upper rear fins 168 is positioned forward of the upper end of the leading edge of the given one of the upper rear fins 168. The slanting of the upper rear fins 168 can improve airflow entry into the upper rear fins 168, reduce pressure loss, enhance heat transfer, and reduce noise due to the gradual airflow transition into the upper rear fins 168. The upper rear fins 168 include a central section and two outer sections arranged on opposing sides of the central section. The fins in the central section of the upper rear fins 168 extend a greater longitudinal distance than the fins of the outer sections of the upper rear fins 168. In one or more other examples, the upper rear fins 168 are not slanted at their forward ends.

The rear fin stack 130 also includes a distributor 172 positioned forward of the lower rear fins 170, e.g., along the X-direction. Like the lower rear fins 170, the distributor 172 is positioned below the horizontal portion 148 of the vapor chamber 132 along the Z-direction. The distributor 172 defines a plenum 174 that is operable to receive “bleed air” as will be explained in detail further herein. The distributor 172 is operable to distribute the received bleed air to the lower rear fins 170 for cooling the horizontal portion 148 of the vapor chamber 132.

The VLC system 100A also includes power supply units (PSUs), or first PSUs 176A and second PSUs 176B, located at the first and second sides 106, 108, respectively, at or near the back 104. The first and second PSUs 176A, 176B are operable to supply electrical power to the power-consuming devices of the VLC system 100A.

In addition, the VLC system 100A includes a plurality of fans 180. The fans 180 are stacked at the back 104 and are arranged to move a fluid (e.g., air) through the VLC system 100A, with a primary airflow direction extending parallel with the X-direction. In this example, the plurality of fans 180 are stacked in three (3) rows, including a top row, middle row, and a bottom row. The fans of the top row are small fans 180A, while the fans of the middle and bottom rows are large fans 180B. The large fans 180B are large relative to the small fans 180A. In this regard, the small fans 180A are small relative to the large fans 180B. Other fan arrangements are possible. For instance, in at least one example, the fans 180 can each be the same size, there may be a different number of rows of fans, etc.

The VLC system 100A includes a plurality of ducts each defining airflow paths. For instance, the VLC system 100A includes an IC duct 182 extending from the front 102 to the back 104, and in this example, arranged centrally within the chassis 114. The IC duct 182 is formed by a first forward wall 184 and a second forward wall 186. The first forward wall 184 and the second forward wall 186 are both positioned forward of the PCB 116, e.g., along the X-direction. The first forward wall 184 is positioned laterally between the front fin stack 128 and the first cage assembly 120A, e.g., along the Y-direction, and the second forward wall 186 is positioned laterally between the front fin stack 128 and the second cage assembly 120B, e.g., along the Y-direction. In at least one example, both the first forward wall 184 and the second forward wall 186 are each formed in part by respective panels of a casing of the front fin stack 128, and both in part by respective divider panels that are attached to their respective panels of the casing of the front fin stack 128. The divider panels each extend vertically above the front fin stack 128 and each have a top edge that is arranged at substantially the same vertical height as the top edge of the PCB 116.

The IC duct 182 is also formed by a first rear wall 188 and a second rear wall 190. The first rear wall 188 and the second rear wall 190 are both positioned rearward of the PCB 116, e.g., along the X-direction. The rear fin stack 130 is positioned laterally between the first rear wall 188 and the second rear wall 190, e.g., along the Y-direction. In this regard, the rear fin stack 130 is enclosed within the IC duct 182. The first rear wall 188 and the second rear wall 190 each extend longitudinally from the rear face of the PCB 116 to a first set of the fans 180. In this example, the first set of the fans includes four (4) small fans 180A and four (4) large fans 180B (two (2) large fans from the middle row and two (2) large fans from the bottom row). Moreover, in this example, the IC duct 182 has a transition section 192 where the lateral width of the IC duct 182 transitions to a wider lateral width. At the transition section 192, the first rear wall 188 and the second rear wall 190 laterally fan out or diverge away from one another along the Y-direction. In this way, the IC duct 182 is laterally wider at the first set of the fans 180 than at the rear of the rear fin stack 130. The IC duct 182 defines an IC airflow path 194. Air moved along the IC airflow path 194 provides cooling to the IC 118 (FIG. 2) as well as to other components within the IC airflow path 194.

The VLC system 100A also includes a first PSU duct 196A and a second PSU duct 196B, which are positioned laterally on opposite sides of the IC duct 182 and at the first side 106 and the second side 108, respectively. The first PSU duct 196A is formed by a first inlet tunnel 198A (or first snorkel inlet), a first divider wall 200A, and a first outer plate 202A of the chassis 114. The first PSU duct 196A defines a first PSU airflow path 204A. Air moved along the first PSU airflow path 204A provides cooling to the first PSUs 176A as well as to other components within the first PSU airflow path 204A. The second PSU duct 196B is formed by a second inlet tunnel 198B (or second snorkel inlet), a second divider wall 200B, and a second outer plate 202B of the chassis 114. The second PSU duct 196B defines a second PSU airflow path 204B. Air moved along the second PSU airflow path 204B provides cooling to the second PSUs 176B as well as to other components within the second PSU airflow path 204B.

The VLC system 100A also includes a first cage duct 206A and a second cage duct 206B, which are positioned laterally on opposite sides of the IC duct 182. The first cage duct 206A is positioned laterally between the IC duct 182 and the first PSU duct 196A, e.g., along the Y-direction, and the second cage duct 206B is positioned laterally between the IC duct 182 and the second PSU duct 196B, e.g., along the Y-direction.

Forward of the PCB 116, the first cage duct 206A is formed between the first forward wall 184 and the first inlet tunnel 198A. The first cages 122A and the first optical connectors 124A allow air to pass therethrough, and a plurality of holes defined by the PCB 116 allows the air to pass rearward of the PCB 116. In at least one example, the PCB 116 defines cage holes and drain holes. The cage holes are each aligned (laterally and vertically), at least in part, with at least one of the first cages 122A. Multiple cage holes can be aligned with a given one of the first cages 122A. The drain holes can be offset from the first cages 122A (laterally and vertically), and can be greater in size than the cage holes. Both the cage holes and the drain holes can allow air to pass through the PCB 116. The second cage duct 206B is formed by the second forward wall 186 and the second inlet tunnel 198B. The second cages 122B and the second optical connectors 124B allow air to pass therethrough, and a plurality of holes defined by the PCB 116 allows the air to pass rearward of the PCB 116. In at least one example, the PCB 116 defines cage holes and drain holes. The cage holes are each aligned (laterally and vertically), at least in part, with at least one of the second cages 122B. Multiple cage holes can be aligned with a given one of the second cages 122B. The drain holes can be offset from the second cages 122B (laterally and vertically), and can be greater in size than the cage holes. Both the cage holes and the drain holes can allow air to pass through the PCB 116.

Rearward of the PCB 116, the first cage duct 206A is formed by the first rear wall 188 and a first outer rear wall formed in part by the first divider wall 200A and the casings of the first PSUs 176A. The second cage duct 206B is formed by the second rear wall 190 and a second outer rear wall formed in part by the second divider wall 200B and the casings of the second PSUs 176B. The first cage duct 206A defines a first cage airflow path 208A, while the second cage duct 206B defines a second cage airflow path 208B. Air moved along the first cage airflow path 208A provides cooling to the first cages 122A and the first optical connectors 124A as well as to other components within the first cage airflow path 208A. Air moved along the second cage airflow path 208B provides cooling to the second cages 122B and the second optical connectors 124B as well as to other components within the second cage airflow path 208B.

The VLC system 100A also includes bleed ducts, including a first bleed duct 210A and a second bleed duct 210B. The first bleed duct 210A fluidly couples the first PSU airflow path 204A with the IC airflow path 194, and the second bleed duct 210B fluidly couples the second PSU airflow path 204B with the IC airflow path 194.

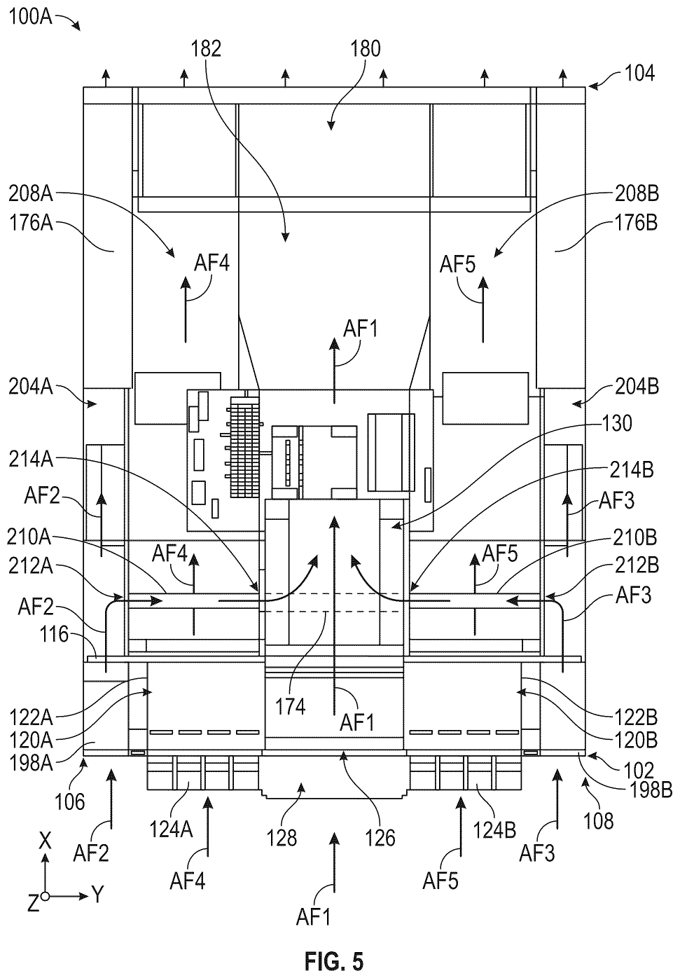

As shown in FIGS. 1 and 5, the first bleed duct 210A is positioned rearward of the PCB 116 along the X-direction, and extends laterally between the first PSU duct 196A and the rear fin stack 130 along the Y-direction. The first bleed duct 210A extends through, but is fluidly isolated from, the first cage airflow path 208A. The first bleed duct 210A has an inlet 212A and an outlet 214A. The inlet 212A of the first bleed duct 210A is in communication with an opening defined by the first divider wall 200A, while the outlet 214A of the first bleed duct 210A is in communication with the plenum 174 formed by the distributor 172 of the rear fin stack 130. A portion of the air moving along the first PSU duct 196A can “bleed” into the first bleed duct 210A and can travel laterally through the first bleed duct 210A to the plenum 174 of the distributor 172. The distributor 172 can distribute the bleed air received from the first bleed duct 210A across the fins of the rear fin stack 130, causing the bleed air to carry heat away from the fins of the rear fin stack 130 to provide cooling to nearby components, such as the vapor chamber 132. In this regard, relatively cool air, which has not passed through the front fin stack 128, can be directed to the rear fin stack 130 for cooling components rearward of the PCB 116.

The second bleed duct 210B is positioned rearward of the PCB 116 along the X-direction, and extends laterally between the second PSU duct 196B and the rear fin stack 130 along the Y-direction. The second bleed duct 210B extends through, but is fluidly isolated from, the second cage airflow path 208B. The second bleed duct 210B has an inlet 212B and an outlet 214B. The inlet 212B of the second bleed duct 210B is in communication with an opening defined by the second divider wall 200B, while the outlet 214B of the second bleed duct 210B is in communication with the plenum 174 formed by the distributor 172 of the rear fin stack 130. A portion of the air moving along the second PSU duct 196B can “bleed” into the second bleed duct 210B and can travel laterally through the second bleed duct 210B to the plenum 174 of the distributor 172. The distributor 172 can distribute the bleed air received from the second bleed duct 210B across the fins of the rear fin stack 130, causing the bleed air to carry heat away from the fins of the rear fin stack 130 to provide cooling to nearby components. Thus, relatively cool air, which has not passed through the front fin stack 128, can be directed to the rear fin stack 130 for cooling components rearward of the PCB 116.

With reference now to FIGS. 1 through 6, an example manner in which air is moved through the VLC system 100A by the fans 180 from the front 102 to the back 104 will now be described. Airflow AF is moved through the VLC system 100A through the various airflow paths.

Airflow AF1 is movable along the IC airflow path 194 defined by the IC duct 182 for cooling the IC 118 and other components in the following example manner. The airflow AF1 enters the IC airflow path 194 by flowing directly into the front fin stack 128 and by bypassing and directly flowing into the rear fin stack 130 by traveling through the upper slot 166 defined by the PCB 116.

A majority of the airflow AF1 that has entered the front fin stack 128 is directed downward to the lower slot 160 by the front fins 136. The front fins 136 are oriented with an angle or “rearward lean” to guide the airflow AF1 downward toward the lower slot 160. The downward-directed airflow AF1 is guided through the lower slot 160 by the guide vane 162 to a position rearward of the PCB 116. The airflow AF1 moved across the front fins 136 carries away heat generated by the IC 118. Specifically, the heat generated by the IC 118 is transferred to the vertical portion 146 of the vapor chamber 132 by way of the TIM 152 and the pedestal 150. The vertical portion 146 of the vapor chamber 132 spreads and transfers the heat to the heat pipes 154, as well as to the horizontal portion 148 of the vapor chamber 132. The heat is transferred from the heat pipes 154 to the front fins 136, and from the front fins 136 to the airflow AF1 passing across the front fins 136. Accordingly, a majority of the airflow Af1 passing through the front fin stack 128 is directed downward toward and through the lower slot 160, carrying away heat generated by the IC 118. The airflow AF1 is guided through the lower slot 160 by the guide vane 162 and is directed upward by the guide vane 162, the ramp 164, and by natural convection to flow across the fins of the power module heat sink 144, e.g., to cool the power module 142. The upward directed airflow AF1 that has passed through the lower slot 160 also flows across the lower rear fins 170 for carrying away heat from the horizontal portion 148 of the vapor chamber 132, which assists with cooling the IC 118. Thereafter, the airflow AF1 continues moving rearward along the IC airflow path 194 toward the back 104. The fans 180 associated with the IC airflow path 194 expel the airflow AF1 out of the back 104.

A portion of the airflow AF1 flows directly to the rear fin stack 130 through the upper slot 166, and a portion of the airflow AF1 that has passed through the front fin stack 128 rises to combine therewith to flow through the upper slot 166. This combined airflow passes through the upper slot 166 and to the rear fins 140. Heat generated by the IC 118 spreads to the horizontal portion 148 of the vapor chamber 132, and this heat is transferred to the rear fins 140, including the upper rear fins 168 and the lower rear fins 170. The combined airflow that has passed through the upper slot 166 flows across the upper rear fins 168 to carry heat toward the back 104. As noted above, some of the airflow AF1 that has passed through the lower slot 160 flows across the lower rear fins 170 to carry heat toward the back 104.

Air also enters the IC airflow path 194 by “bleeding” into the IC duct 182 by way of the first bleed duct 210A and the second bleed duct 210B. The first bleed duct 210A fluidly couples the first PSU airflow path 204A with the IC airflow path 194, and the second bleed duct 210B fluidly couples the second PSU airflow path 204B with the IC airflow path 194. A portion of an airflow AF2 (i.e., a cooling airflow) moving along the first PSU duct 196A can “bleed” into the first bleed duct 210A, and can travel laterally along the Y-direction through the first bleed duct 210A to the plenum 174 of the distributor 172. Similarly, a portion of an airflow AF3 moving along the second PSU duct 196B can “bleed” into the second bleed duct 210B, and can travel laterally along the Y-direction through the second bleed duct 210B to the plenum 174 of the distributor 172. The distributor 172 can distribute the bleed air received from the first bleed duct 210A and the second bleed duct 210B to the lower rear fins 170. The bleed air distributed to the lower rear fins 170 combines with the portion of the airflow AF1 that has passed through the lower slot 160. Accordingly, the combined airflow flows across the lower rear fins 170, causing heat to be carried away from the lower rear fins 170, which ultimately cools the IC 118. In this regard, relatively cool air, which has not passed through the front fin stack 128, can be directed to the lower rear fins 170 for enhanced cooling of the IC 118.

Airflow AF2 is movable along the first PSU airflow path 204A defined by the first PSU duct 196A for cooling the first PSUs 176A. The airflow AF2 enters the first PSU airflow path 204A by flowing into the first inlet tunnel 198A. The airflow AF2 passes through the first inlet tunnel 198A and passes rearward of the PCB 116 through a first vent cutout 216A defined by the PCB 116. The first vent cutout 216A is formed by the PCB 116 in an upper corner in this example, e.g., as shown in FIG. 3. The first vent cutout 216A is sized complementary to the first inlet tunnel 198A. Once the airflow AF2 passes rearward of the PCB 116, the airflow AF2 is guided generally downward and rearward to the first PSUs 176A by a first PSU guide ramp. The first PSU guide ramp has a forward end and a rear end. The forward end of the first PSU guide ramp is coupled with the PCB 116, e.g., just below the first vent cutout 216A. The rear end of the first PSU guide ramp is coupled with a horizontally-oriented PCB 218. The airflow AF2 is guided downward and rearward to the first PSUs 176A for providing cooling thereto. The airflow AF2 can be expelled from the first PSUs 176A at the back 104. Moreover, as noted above, a portion of the airflow AF2 can bleed into the first bleed duct 210A and travel to the distributor 172, which can distribute the bleed air from the airflow AF2 to mix with the airflow AF1 for carrying heat away from the lower rear fins 170 to provide cooling to the IC 118.

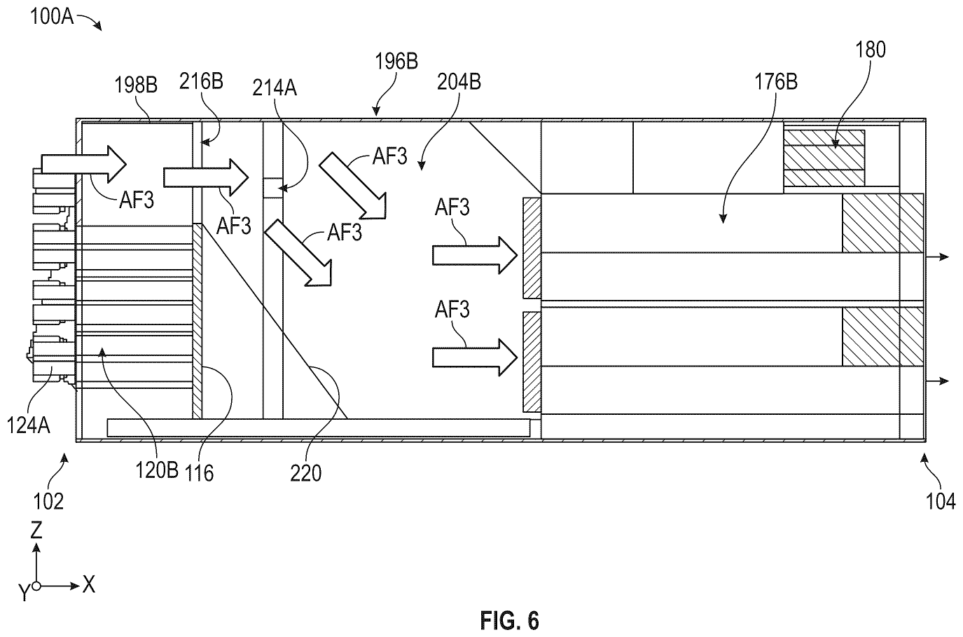

Airflow AF3 is movable along the second PSU airflow path 204B defined by the second PSU duct 196B for cooling the second PSUs 176B. The airflow AF3 enters the second PSU airflow path 204B by flowing into the second inlet tunnel 198B. The airflow AF3 passes through the second inlet tunnel 198B and passes rearward of the PCB 116 through a second vent cutout 216B defined by the PCB 116. The second vent cutout 216B is formed by the PCB 116 in an upper corner in this example, e.g., as shown in FIG. 3. The second vent cutout 216B is sized complementary to the second inlet tunnel 198B. Once the airflow AF3 passes rearward of the PCB 116, the airflow AF3 is guided generally downward and rearward to the second PSUs 176B by a second PSU guide ramp 220, e.g., as shown in FIGS. 1 and 6. The second PSU guide ramp 220 has a forward end and a rear end. The forward end of the second PSU guide ramp 220 is coupled with the PCB 116, e.g., just below the second vent cutout 216B. The rear end of the second PSU guide ramp 220 is coupled with the horizontally-oriented PCB 218. The airflow AF3 is guided downward and rearward to the second PSUs 176B for providing cooling thereto. The airflow AF3 can be expelled from the second PSUs 176B at the back 104. Moreover, as noted above, a portion of the airflow AF3 can bleed into the second bleed duct 210B and travel to the distributor 172, which can distribute the bleed air from the airflow AF3 to mix with the airflow AF1 for carrying heat away from the lower rear fins 170 to provide cooling to the IC 118.

Airflow AF4 is movable along the first cage airflow path 208A defined by the first cage duct 206A for cooling the first PSUs 176A. The airflow AF4 moved along the first cage airflow path 208A provides cooling to the first cages 122A and the first optical connectors 124A as well as to other components within the first cage airflow path 208A. Specifically, the first cages 122A and the first optical connectors 124A allow air to pass therethrough, which cools these components. The cage holes defined by the PCB 116 are aligned, at least in part, with the first cages 122A (laterally and vertically), allowing air that has passed through the first optical connectors 124A and the first cages 122A to flow rearward of the PCB 116. The drain holes defined by the PCB 116, which are offset from the first cages 122A (laterally and vertically), promote lateral movement of the airflow AF4 just forward of the PCB 116, providing enhanced cooling to the first cages 122A, the first optical connectors 124A, the IC 118, etc. The drain holes, which are larger than the cage holes, allow for the lateral airflow just forward of the PCB 116 to “drain” rearward of the PCB 116. The airflow AF4 that has passed rearward of the PCB 116 continues rearward along the first cage airflow path 208A to a first cage fan set of the fans 180. The first cage fan set includes two (2) small fans 180A, which are arranged on one (1) row, and two (2) large fans 180B, which are arranged in two (2) rows. The first cage airflow path 208A provides a dedicated airflow path for cooling the first cages 122A of the first cage assembly 120A and the first optical connectors 124A. The first cage airflow path 208A is fluidly isolated from the IC airflow path 194 and the first PSU airflow path 204A, despite being positioned laterally therebetween.

Airflow AF5 is movable along the second cage airflow path 208B defined by the second cage duct 206B for cooling the second PSUs 176B. The airflow AF5 moved along the second cage airflow path 208B provides cooling to the second cages 122B and the second optical connectors 124B as well as to other components within the second cage airflow path 208B. Specifically, the second cages 122B and the second optical connectors 124B allow air to pass therethrough, which cools these components. The cage holes defined by the PCB 116 are aligned, at least in part, with the second cages 122B (laterally and vertically), allowing air that has passed through the second optical connectors 124B and the second cages 122B to flow rearward of the PCB 116. The drain holes defined by the PCB 116, which are offset from the second cages 122B (laterally and vertically), promote lateral movement of the airflow AF5 just forward of the PCB 116, providing enhanced cooling to the second cages 122B, the second optical connectors 124B, the IC 118, etc. The drain holes, which are larger than the cage holes, allow for the lateral airflow just forward of the PCB 116 to “drain” rearward of the PCB 116. The airflow AF5 that has passed rearward of the PCB 116 continues rearward along the second cage airflow path 208B to a second cage fan set of the fans 180. The second cage fan set includes two (2) small fans 180A, which are arranged on one (1) row, and two (2) large fans 180B, which are arranged in two (2) rows. The second cage airflow path 208B provides a dedicated airflow path for cooling the second cages 122B of the second cage assembly 120B and the second optical connectors 124B. The second cage airflow path 208B is fluidly isolated from the IC airflow path 194 and the second PSU airflow path 204B, despite being positioned laterally therebetween.

In at least one example, the fans 180 associated with the IC duct 182 are controllable independently of the remainder of the fans 180, e.g., so that the mass flow rates of the airflows can be controlled to meet the cooling demands of the IC 118 and other components whilst also minimizing the power usage to drive the fans 180. The fans 180 can be controlled based on feedback from one or more sensors of the VLC system 100A (e.g., temperature sensors, flow sensors, etc.), e.g., by a computing system of the VLC system 100A having one or more processors and one or more memory devices (e.g., one or more non-transitory computer readable medium). Feedback from the one or more sensors can indicate the heat load of the IC 118 and/or other heat-generating components. The one or more processors can control the fans 180 based at least in part on the heat load. For instance, when an increase in heat load is detected, the fans 180 associated with the IC duct 182 can be controlled so that the mass flow rate of the airflow AF1 is increased, e.g., for enhanced cooling of the IC 118. The other fans 180 can be controlled to maintain the mass flow rates of the other airflows, or can be controlled to change their mass flow rates. Also, when the optical components are experiencing an increased heat load, but the heat load of the IC 118 has not increased or not increased beyond a threshold, the fans 180 associated with moving the airflows AF4, AF5 can be controlled to increase the mass flow rates of airflows AF4, AF5, while the fans 180 associated with the airflow AF1 can be controlled differently.

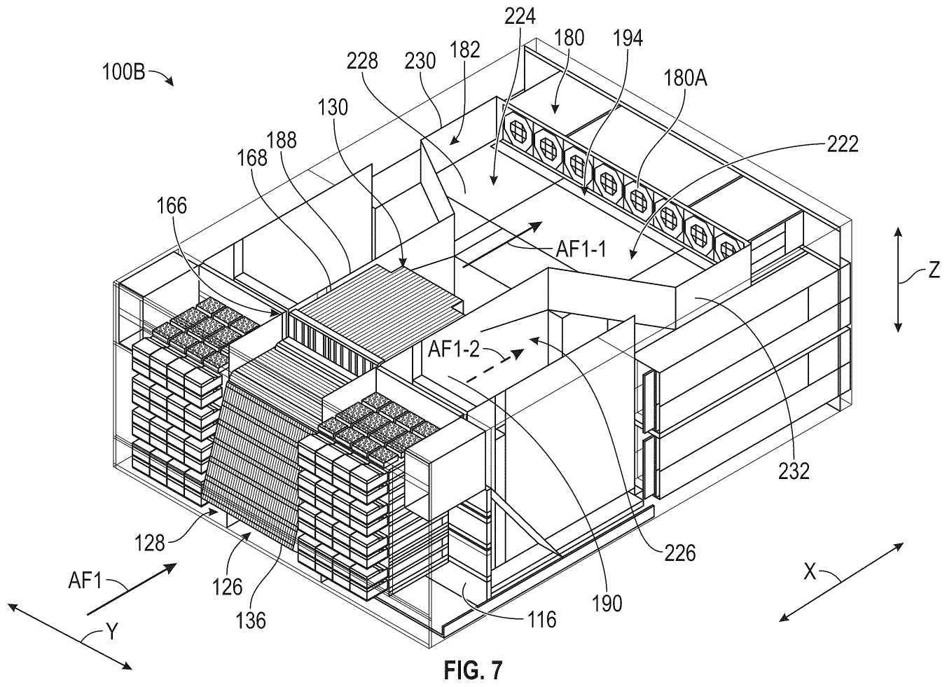

FIG. 7 is a perspective view of a VLC system 100B, according to one or more aspects of the present disclosure. The VLC system 100B is configured in a similar manner as the VLC system 100A of FIGS. 1 through 6, except as provided below. Accordingly, like numerals will refer to like structures below.

As depicted in FIG. 7, the IC duct 182 is configured such that the airflow AF1 traveling along the IC airflow path 194 is split into an upper airflow AF1-1 and a lower airflow AF-2. Particularly, as illustrated in FIG. 7, the IC duct 182 includes a splitter 222 that splits the IC duct 182 into an upper channel 224 and a lower channel 226, or rather, that separates the IC airflow path 194 into an upper airflow path along which the upper airflow AF-1 travels and a lower airflow path along which the lower airflow AF-2 travels.

The splitter 222 extends from the first and second rear walls 188, 190 to the fans 180 along the X-direction. The splitter 222 has a floor 228 and sidewalls connected to the floor 228. The sidewalls include a first upper rear sidewall 230 and a second upper rear sidewall 232. The first upper rear sidewall 230 extends from the first rear wall 188 rearward to the fans 180. The second upper rear sidewall 232 extends from the second rear wall 190 rearward to the fans 180, mirroring the first upper rear sidewall 230. The first upper rear sidewall 230 and the second upper rear sidewall 232 each laterally widen along the Y-direction (e.g., away from a longitudinal centerline of the VLC system 100B) so that the upper channel 224 is wider at the fans 180 than at the rear end of the rear fin stack 130. The floor 228 also widens correspondingly. Accordingly, as shown in FIG. 7, the upper channel 224 is associated with eight (8) of the small fans 180A of the top row of the fans 180 and the lower channel 226 is associated with four (4) large fans 180B (hidden in FIG. 7; see FIG. 1) of the bottom two rows of the fans 180.

During operation, a portion of the airflow AF1 bypasses the front fin stack 128 of the IC heat sink 126 and flows directly over the front fin stack 128 and through the upper slot 166 of the PCB 116 to the rear fin stack 130. Some of the airflow AF1 that has passed through the front fin stack 128 combines with this bypass airflow. This combined airflow flows across the upper rear fins 168 of the rear fin stack 130, and this example, flows as airflow AF-1 along the upper channel 224, e.g., to the eight (8) small fans 180A. The airflow AF1-1 is thus dedicated to carrying heat away from the upper rear fins 168, which cools the upper face of the horizontal portion of the vapor chamber, which in turn cools the IC.

Further, during operation, a portion of the airflow AF1 enters the front fin stack 128 and is directed rearward and downward to the lower slot defined by the PCB 116. This portion of the airflow AF1 travels rearward of the PCB 116 as airflow AF-2 to cool the power module and flow across the lower rear fins of the rear fin stack 130. The airflow AF-2 flows along the lower channel 226 to four (4) of the large fans 180B (hidden in FIG. 7; see FIG. 1) of the bottom two rows of the fans 180. The airflow AF-2 is thus dedicated to carrying heat away from the front fins 136 of the front fin stack 128, e.g., to provide cooling to the IC, and rearward of the PCB 116, for carrying heat away from the power module heat sink and the lower rear fins of the rear fin stack 130, e.g., for cooling the lower face of the horizontal portion of the vapor chamber, which in turn cools the IC. Bleed flow from the first and second PSU ducts can also combine with the airflow that has passed through the lower slot to form the airflow AF-2.

In at least one example, the small fans 180A associated with the upper channel 224 can be controlled independently of the large fans associated with the lower channel 226, e.g., to control the mass flow rates of the airflow AF-1 and the airflow AF2-2 to meet the cooling demands of the IC and other components whilst also minimizing the power usage to drive the fans 180.

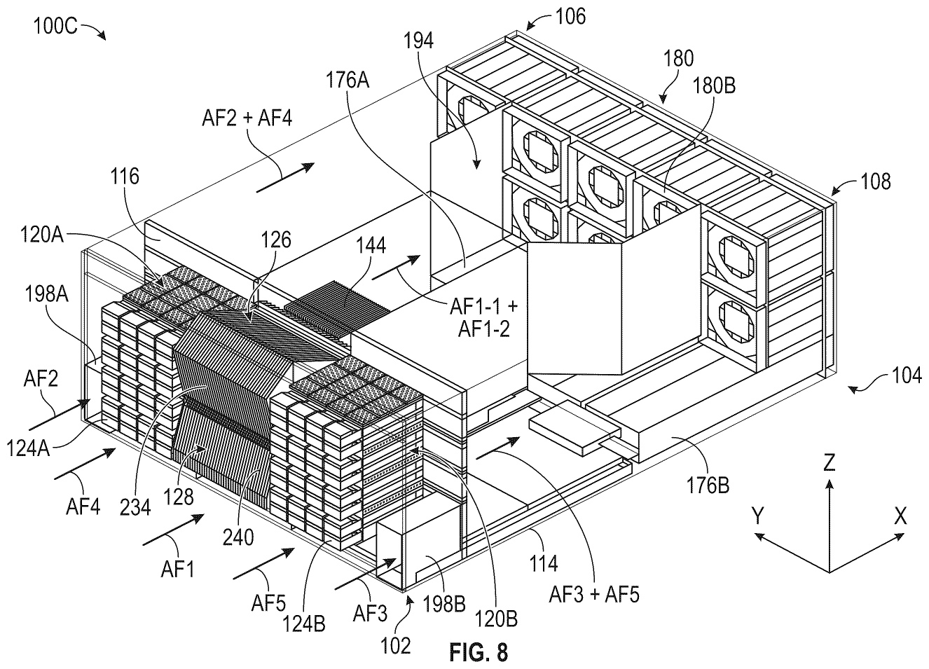

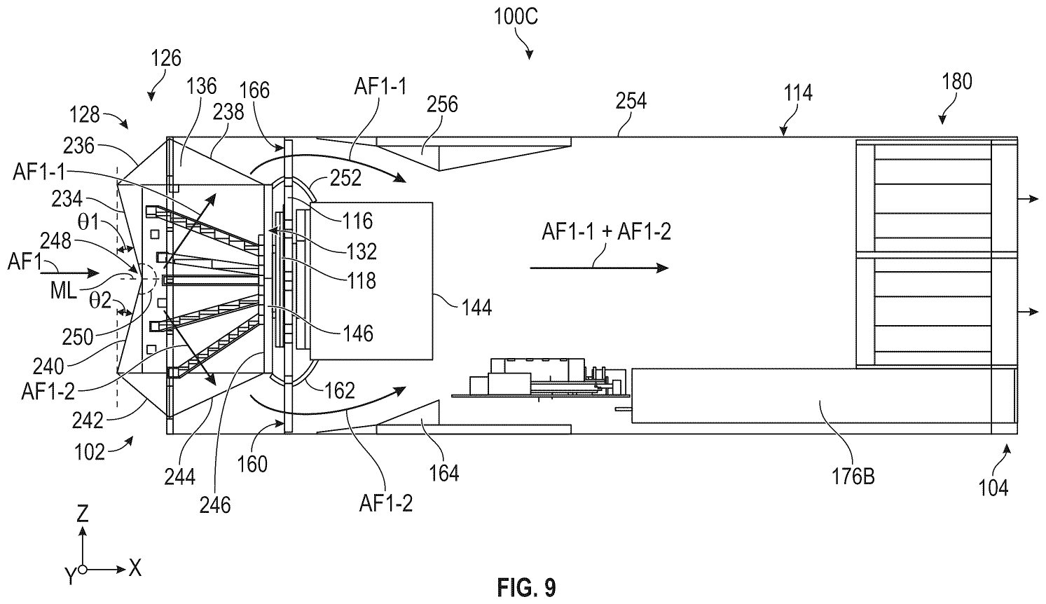

FIGS. 8 and 9 provide views of a VLC system 1000, according to one or more aspects of the present disclosure. FIG. 8 is a perspective view of the VLC system 1000. FIG. 9 is a side cross-sectional view of the VLC system 1000. The VLC system 1000 is configured in a similar manner as the VLC system 100A of FIGS. 1 through 6, except as provided below. Accordingly, like numerals will refer to like structures below.

As depicted in FIGS. 8 and 9, the IC heat sink 126 includes the front fin stack 128 positioned forward of the vertically-oriented PCB 116. However, in this example, the IC heat sink 126 does not include a rear fin stack positioned rearward of the PCB 116. Moreover, notably, the front fin stack 128 of FIGS. 8 and 9 has front fins 136 arranged so that a portion of the incoming airflow AF1 that moves through the front fin stack 128 is directed upward to the upper slot 166, as represented by airflow AF-1 in FIG. 9, and so that a portion of the incoming airflow AF1 that moves through the front fin stack 128 is directed downward to the lower slot 160, as represented by airflow AF-2 in FIG. 9.

In at least one example, the front fins 136 have a concave side profile, e.g., as shown in FIG. 9, such as an heptagonal concave profile. As used herein, a concave side profile has at least one interior angle greater than one hundred eighty degrees (180°), and a convex side profile has all interior angles less than one hundred eighty degrees (180°). The front fins 136 form an upper forward face 234, a forward roof face 236, and a rear roof face 238, which collectively define the profile of an upper half of the front fins 136. The front fins 136 also form a lower forward face 240, a forward floor face 242, and a rear floor face 244, which collectively define the profile of a lower half of the front fins 136. The upper half of the front fins 136 is mirrored along a vertical midline ML. The front fins 136 also form a rear face 246 that connects to the vertical portion 146 of the vapor chamber 132. In this example, the vapor chamber 132 has the vertical portion 146, but does not include a horizontal portion.

The upper forward face 234 is slanted at an angle θ1 with respect to the Z-direction, while the lower forward face 240 is slanted at an angle θ2 with respect to the Z-direction. In at least one example, angle θ1 and angle θ2 are equal or substantially equal in magnitude, but have opposite signs. In at least one example, angle θ1 is between negative ten (−10°) and negative twenty (−20°), including the endpoints, and angle θ2 is between ten and twenty degrees (between 10° and 20°), including the endpoints. The upper forward face 234 has a negative slope from the viewpoint in FIG. 9 and the lower forward face 240 has a positive slope from the viewpoint in FIG. 9. The upper forward face 234 and the lower forward face 240 meet at a valley 248. An interior angle 250 associated with the valley 248 is greater than one hundred eighty degrees (180°). Thus, the front fins 136 form a concave side profile, with the upper forward face 234 and the lower forward face 240 being connected to one another at the vertical midline ML and forming an interior angle greater than one hundred eighty degrees (180°). The upper forward face 234 and the lower forward face 240 have slopes with opposite signs (e.g., from the viewpoint in FIG. 9, the upper forward face 234 has a negative slope and the lower forward face 240 has a positive slope).

Advantageously, the front fins 136 are arranged so that the upper half of the front fins 136 guides the incoming airflow AF1 upward to the upper slot 166 of the PCB 116 while the lower half of the front fins 136 guides the incoming airflow AF1 downward to the lower slot 160 of the PCB 116, e.g., as shown in FIG. 9. In this way, the airflow AF1 can carry heat generated by the IC 118 away from the front fins 136 to a position rearward of the PCB 116 through respective slots defined by the PCB 116 above and below the IC 118.

In one or more examples, an upper guide vane 252 is arranged at the upper slot 166, while the guide vane 162 (or lower guide vane in such examples) is arranged at the lower slot 160. The upper guide vane 252 has a curved face to guide the airflow AF1-1 into and through the upper slot 166. In the depicted example of FIG. 9, the upper guide vane 252 has a convex shape with respect to the upper slot 166. In this regard, the upper guide vane 252 directs the airflow AF1-1 guided upward by the upper half of the front fins 136 into the upper slot 166 in a smooth and efficient manner, which can reduce pressure losses and provide a more consistent airflow through the upper slot 166. The convex curvature of the upper guide vane 252 rearward of the PCB 116 can gradually guide the airflow rearward and downward, e.g., so as to be directed at a top side of the power module heat sink 144. In this way, the airflow AF-1 that has passed through the upper slot 166 can move across the fins of the power module heat sink 144, which ultimately provides cooling to the power module 142. In at least one example, the upper guide vane 252 is coupled with, or forms a part of, the vertical portion 146 of the vapor chamber 132. In this example, the upper guide vane 252 extends from the vertical portion 146 to the top side of the power module heat sink 144.

The guide vane 162 directs the airflow AF-2 guided downward by the lower half of the front fins 136 into the lower slot 160 in a smooth and efficient manner, which can reduce pressure losses and provide a more consistent airflow through the lower slot 160. The convex curvature of the guide vane 162 rearward of the PCB 116 can gradually guide the airflow AF1-2 rearward and upward, e.g., so as to be directed at the power module heat sink 144. In this way, the airflow AF that has passed through the lower slot 160 can move through the bottom side of the fins of the power module heat sink 144, which ultimately provides cooling to the power module 142. In this example, the guide vane 162 extends from the vertical portion 146 to the bottom side of the power module heat sink 144.

In one or more examples, a top plate 254 of the chassis 114 includes an upper ramp 256 positioned rearward of the upper slot 166. The upper ramp 256 provides an aerodynamic feature that guides air that has passed through the upper slot 166 downward to flow across the top side of the vertically-oriented fins of the power module heat sink 144. Accordingly, the upper ramp 256 can enhance the cooling of the power module 142, especially when used in combination with the upper guide vane 252. Specifically, the upper ramp 256 and the upper guide vane 252 can utilize the Coanda effect to direct the air that has passed through the upper slot 166 across the fins of the power module heat sink 144. The upper guide vane 252 and the upper ramp 256 effectively provide an upper nozzle to direct airflow to the top side of the power module heat sink 144. The ramp 164 (or lower ramp in this example) provides an aerodynamic feature that deflects air that has passed through the lower slot 160 upward to flow across the bottom side of the vertically-oriented fins of the power module heat sink 144. Thus, the ramp 164 can enhance the cooling of the power module 142, especially when used in combination with the guide vane 162. Specifically, the ramp 164 and the guide vane 162 can utilize the Coanda effect to direct the air that has passed through the lower slot 160 across the fins of the power module heat sink 144. The guide vane 162 and the ramp 164 effectively provide a lower nozzle to direct airflow to the bottom side of the power module heat sink 144. Rearward of the power module heat sink 144, the airflow AF1-1 and the airflow AF1-2 can combine and travel rearward to the fans 180, e.g., to a central cluster of six (6) large fans 180B as shown in FIG. 8.

As further shown in FIGS. 8 and 9, in one or more examples, the PSUs can be arranged flat on their sides rather than upright, or stated differently, so that the smallest dimension of a given PSU extends along the Z-direction as opposed to along the Y-direction, as is the case for the second PSU 176B depicted in FIG. 1. In FIGS. 8 and 9, the first PSUs 176A are arranged flat on their sides while the second PSUs 176B are arranged flat on their sides. The two (2) rows of large fans 180B (with five (5) large fans 180B in each of the rows) are stacked on the first and second PSUs 176A, 176B, which allows for additional lateral space within the chassis 114 for more or larger fans.

In addition, in the example of FIGS. 8 and 9, the fans 180 of a first outer column at the first side 106 are arranged to move an airflow AF2 through the first inlet tunnel 198A and toward the first PSUs 176A for providing cooling thereto and also to move an airflow AF4 through the first optical connectors 124A and the first cage assembly 120A (and passed the PCB 116 by way of the cage holes and drain holes) for providing cooling thereto. The airflow AF2 and the airflow AF4 can combine at a position rearward of the PCB 116. Thus, the first PSU airflow path and the first cage airflow path combine rearward of the PCB 116 in this example. In one or more other examples, a dedicated first PSU duct can provide fluid communication between the first inlet tunnel 198A and the first PSUs 176A, which can separate and fluidly isolate the airflow AF2 from the airflow AF4. Also, the first inlet tunnel 198A is in flow communication with a first vent cutout defined by the PCB 116. The first vent cutout is formed by the PCB 116 in a lower corner at the first side 106 in this example, e.g., as shown in FIG. 8. The first vent cutout is sized complementary to the first inlet tunnel 198A.

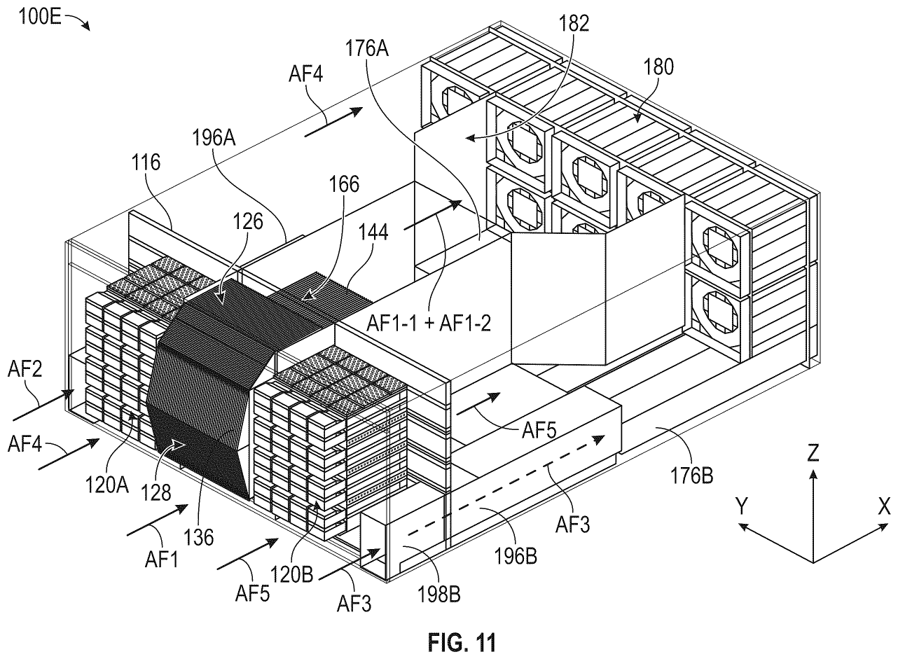

Further, the fans 180 of a second outer column at the second side 108 are arranged to move an airflow AF3 through the second inlet tunnel 198B and toward the second PSUs 176B for providing cooling thereto and also to move an airflow AF5 through the second optical connectors 124B and the second cage assembly 120B (and passed the PCB 116 by way of the cage holes and drain holes) for providing cooling thereto. The airflow AF3 and the airflow AF5 can combine at a position rearward of the PCB 116. Thus, the second PSU airflow path and the second cage airflow path combine rearward of the PCB 116. In one or more other examples, a dedicated second PSU duct can provide fluid communication between the second inlet tunnel 198B and the second PSUs 176B (and example of which is shown in FIG. 11), which can separate and fluidly isolate the airflow AF3 from the airflow AF5. Also, the second inlet tunnel 198B is in flow communication with a second vent cutout defined by the PCB 116. The second vent cutout is formed by the PCB 116 in a lower corner at the second side 108 in this example, e.g., as shown in FIG. 8. The second vent cutout is sized complementary to the second inlet tunnel 198B.

In at least one example, the fans 180 of the center cluster associated with the IC airflow path 194 are controlled independently of the fans 180 of the outer columns, e.g., to control the mass flow rates of the airflows to meet the cooling demands of the IC and other components whilst also minimizing the power usage to drive the fans 180.

Further, as shown in FIGS. 8 and 9, the front fin stack 128 has a greater height than both the first and second cage assemblies 120A, 120B, e.g., along the Z-direction. The front fin stack 128 extends at least to a top end of the upper slot 166, or rather, a top edge of the PCB 116. In this regard, the airflow AF1 that flows through the upper slot 166 first flows through the top portion of the front fin stack 128.

In one or more examples, the splitter 222 depicted in FIG. 7 and its associated aspects can be applied to the example of FIGS. 8 and 9 such that the airflow AF-1 travels to a first set of the fans 180 and the airflow AF-2 travels to a second set of the fans 180 (and airflows AF4 and AF5 travel to a fourth and fifth set of the fans 180), wherein each set of the fans has at least one fan.

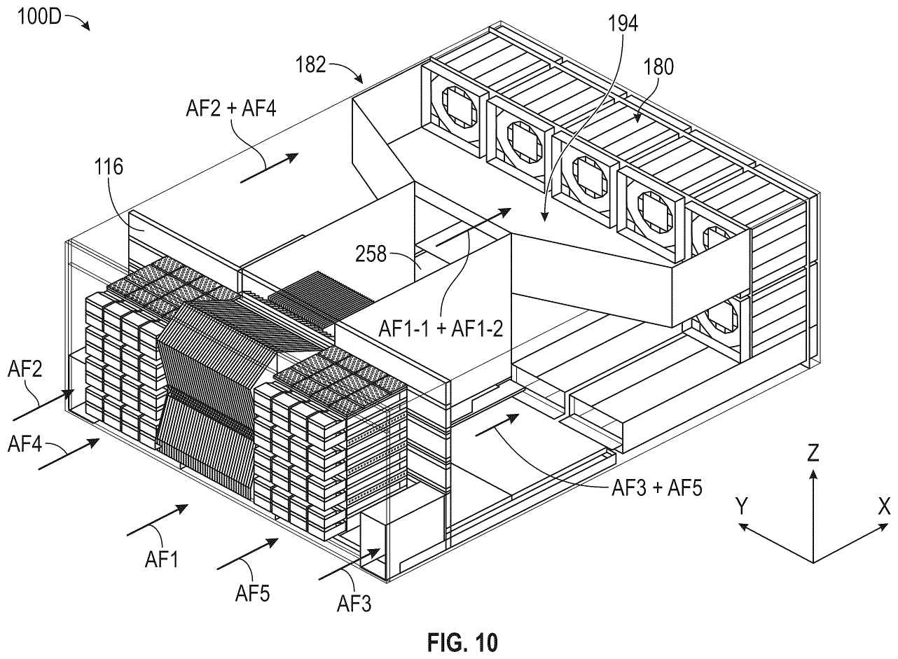

FIG. 10 is a perspective view of the VLC system 100D. The VLC system 100D is configured in a similar manner as the VLC system 100C of FIGS. 8 through 9, except as provided below. Accordingly, like numerals will refer to like structures below.

As illustrated in FIG. 10, the IC duct 182 is configured such that the combined airflow AF-1, AF1-2 traveling along the IC airflow path 194 flows to an upper row of the fans 180. Particularly, as illustrated in FIG. 10, the IC duct 182 includes a ramp 258 that directs the combined airflow AF-1, AF-2 upward to the top row of the fans 180. In this regard, instead of the combined airflow AF-1, AF1-2 flowing to a central cluster of the fans 180, as in the example of FIGS. 8 and 9, the combined airflow AF-1, AF-2 flows to the top row of the fans 180. The other airflows AF2, AF3, AF4, AF5 flow to the bottom row of the fans 180.

In at least one example, the fans 180 of the top row associated with the IC airflow path 194 are controlled independently of the fans 180 of the bottom row, e.g., to control the mass flow rates of the airflows to meet the cooling demands of the IC and other components whilst also minimizing the power usage to drive the fans 180.

FIGS. 11 and 12 provide views of a VLC system 100E and the IC heat sink 126 thereof, according to one or more aspects of the present disclosure. FIG. 11 is a perspective view of the VLC system 100E. FIG. 12 is a side perspective view of the IC heat sink 126. The VLC system 100E is configured in a similar manner as the VLC system 100C of FIGS. 8 and 9, except as provided below. Accordingly, like numerals will refer to like structures below.

As depicted in FIGS. 11 and 12, the IC heat sink 126 includes the front fin stack 128 positioned forward of the vertically-oriented PCB 116, and in this example, the IC heat sink 126 does not include a rear fin stack positioned rearward of the PCB 116. Moreover, the front fin stack 128 of FIGS. 11 and 12 has front fins 136 arranged so that a portion of the incoming airflow AF1 that moves through the front fin stack 128 is directed upward to the upper slot 166 and so that a portion of the incoming airflow AF1 that moves through the front fin stack 128 is directed downward to the lower slot (hidden in FIG. 11). These two airflows AF1-1, AF1-2 recombine rearward of the PCB 116, much like as described above and depicted in FIG. 9. The other airflows AF2, AF3, AF4, AF5 are flowable through the VLC system 110E as previously described. In this example, the first and second PSUs 176A, 176B are cooled by dedicated first and second PSU ducts 196A, 196B.

In at least one example, the front fins 136 have a convex side profile, e.g., as shown in FIG. 12, such as an heptagonal convex profile. As noted previously, a convex side profile has all interior angles less than one hundred eighty degrees (180°). The front fins 136 are formed by the upper forward face 234, the forward roof face 236, and the rear roof face 238, which collectively define the profile of an upper half of the front fins 136. In this example, the rear roof face 238 is perpendicular to the Z-direction. The front fins 136 are also formed by the lower forward face 240, the forward floor face 242, and the rear floor face 244, which collectively define the profile of a lower half of the front fins 136. In this example, the rear floor face 244 is perpendicular to the Z-direction. The front fins 136 are also formed by the rear face 246 that connects to the vertical portion 146 of the vapor chamber 132. In this example, the vapor chamber 132 has the vertical portion 146, but does not include a horizontal portion. Heat pipes 154 fan out within the front fins 136.

The upper half of the front fins 136 is mirrored along a vertical midline ML. The upper forward face 234 is slanted at a first angle with respect to the Z-direction, while the lower forward face 240 is slanted at a second angle with respect to the Z-direction. In at least one example, the first and second angles are equal or substantially equal in magnitude, but have opposite signs. In at least one example, the first angle is between ten and twenty degrees (between 10° and 20°), including the endpoints, and the second angle is between negative ten and negative twenty degrees (between −10° and −20°), including the endpoints. The upper forward face 234 has a positive slope from the viewpoint in FIG. 12 and the lower forward face 240 has a negative slope from the viewpoint in FIG. 12. The upper forward face 234 and the lower forward face 240 meet at a peak 260. The interior angle associated with the peak 260 is less than one hundred eighty degrees (180°), as are all other interior angles. Thus, the front fins 136 form a convex side profile.

The upper forward face 234 has a greater positive slope than does the forward roof face 236 (from the viewpoint in FIG. 12), and the rear roof face 238 has a slope of zero (0). Thus, the faces of the upper half of the front fin stack 128 become less steep from one face to the next, starting at the vertical midline ML and moving toward the top of the front fin stack 128. The lower forward face 240 has a negative slope that is larger in absolute value (that is, more negative) than does the forward floor face 242 (from the viewpoint in FIG. 12), and the rear floor face 244 has a slope of zero (0). Thus, the absolute values of the slopes of the faces of the lower half of the front fin stack 128 decrease from one face to the next, starting at the vertical midline ML and moving toward the bottom of the front fin stack 128. The upper forward face 234 and the lower forward face 240 have slopes with opposite signs (e.g., from the viewpoint in FIG. 12, with the upper forward face 234 having a positive slope and the lower forward face 240 having a negative slope).

Further, as shown in FIG. 11, the front fin stack 128 has a greater height than both the first and second cage assemblies 120A, 120B, e.g., along the Z-direction. The front fin stack 128 extends at least to a top end of the upper slot 166, or rather, a top edge of the PCB 116. In this regard, the airflow AF1 that flows through the upper slot 166 first flows through the top portion of the front fin stack 128.

In at least one example, the fans 180 of the center cluster associated with the IC duct 182 are controlled independently of the fans 180 of the outer columns, e.g., to control the mass flow rates of the airflows to meet the cooling demands of the IC and other components whilst also minimizing the power usage to drive the fans 180.

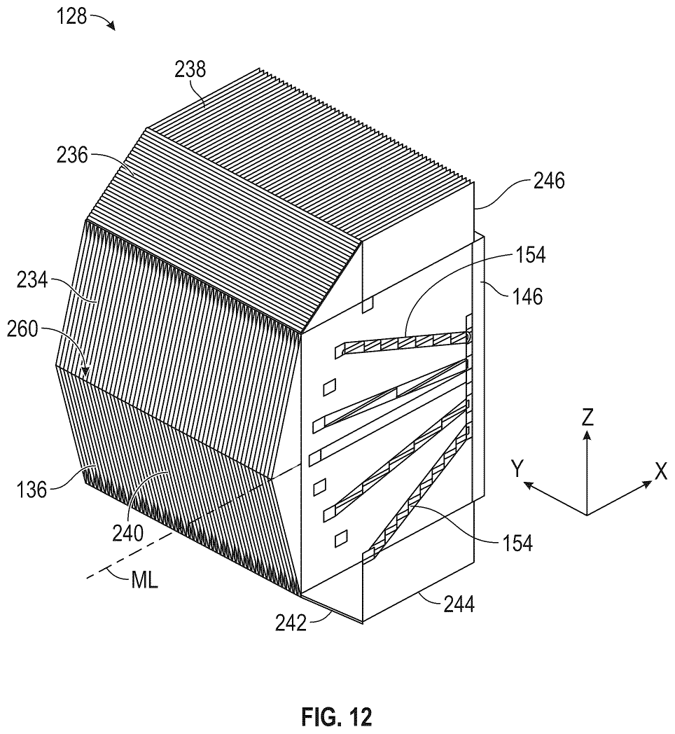

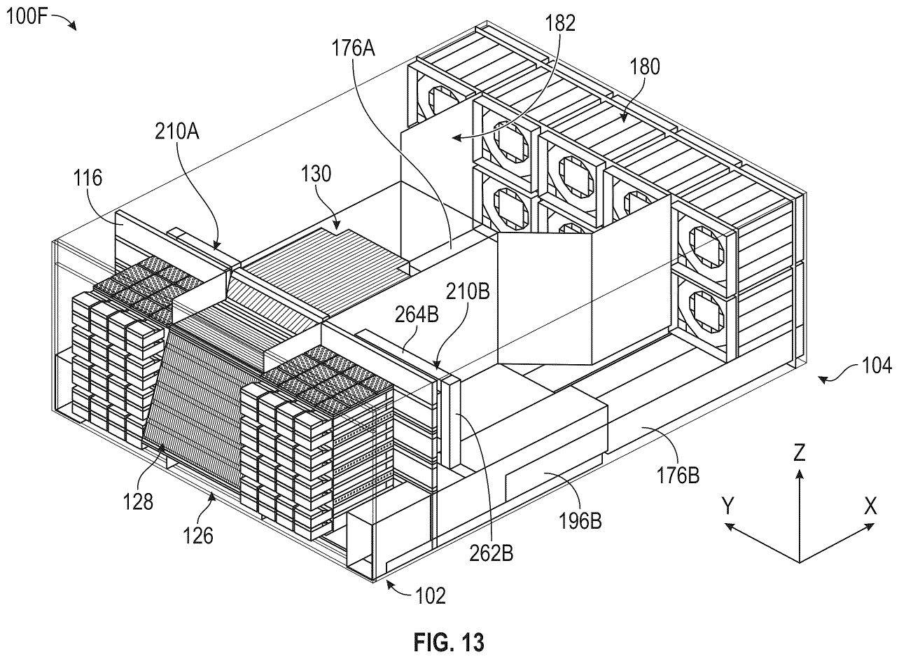

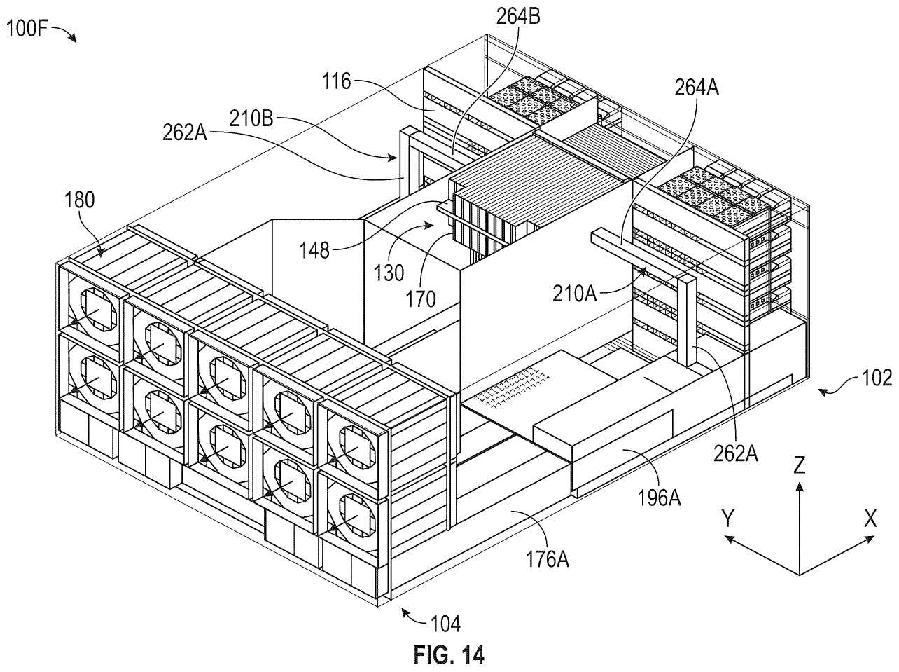

FIGS. 13 and 14 provide perspective views of a VLC system 100F, according to one or more aspects of the present disclosure. FIG. 13 is a front perspective view of the VLC system 100F. FIG. 14 is a rear perspective view of the VLC system 100F. The VLC system 100F is configured in a similar manner as the VLC system 100E of FIG. 11, except as provided below. Accordingly, like numerals will refer to like structures below.

As depicted in the example of FIGS. 13 and 14, the IC heat sink 126 includes the front fin stack 128 positioned forward of the vertically-oriented PCB 116 and the rear fin stack 130 positioned rearward of the PCB 116, much like the VLC system 100A of FIGS. 1 and 7. Moreover, in this example, the first bleed duct 210A has a vertically-oriented segment 262A and a horizontally-oriented segment 264A. In this example, the first bleed duct 210A has an L-shape. The vertically-oriented segment 262A is connected to the first PSU duct 196A and the horizontally-oriented segment 264A is connected to the rear fin stack 130, e.g., to the distributor thereof. Similarly, the second bleed duct 210B has a vertically-oriented segment 262B and a horizontally-oriented segment 264B. In this example, the second bleed duct 210B has an L-shape. The vertically-oriented segment 262B is connected to the second PSU duct 196B and the horizontally-oriented segment 264B is connected to the rear fin stack 130, e.g., to the distributor thereof. The distributor distributes the bleed airflow received from the first and second bleed ducts 210A, 210B to the lower rear fins 170. Accordingly, the bleed air, which has not passed through the front fin stack 128, can mix with the air that has passed through the lower slot to carry heat away from the lower rear fins 170, which can cool the horizontal portion 148 of the vapor chamber. In this way, the IC mounted to the forward face of the PCB 116 can be cooled.

In at least one example, the fans 180 of the center cluster associated with the IC duct 182 are controlled independently of the fans 180 of the outer columns, e.g., to control the mass flow rates of the airflows to meet the cooling demands of the IC and other components whilst also minimizing the power usage to drive the fans 180.

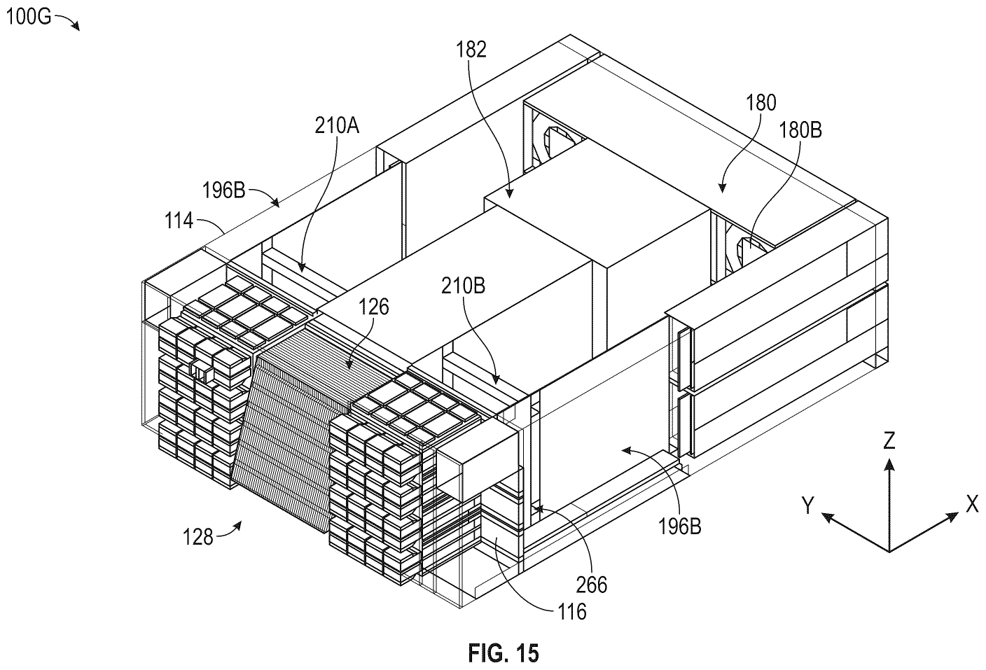

FIG. 15 is a perspective view of the VLC system 100G, according to one or more aspects of the present disclosure. The VLC system 100G is configured in a similar manner as the VLC system 100A of FIG. 1, except as provided below. Accordingly, like numerals will refer to like structures below.

In this example, the PCB 116 is absent an upper slot, but does include the lower slot. The front fin stack 128 of the IC heat sink 126 extends to the top of the chassis 114 as shown in FIG. 15. Also, the fans 180 are arranged in two (2) rows of four (4) large fans 180B.

Moreover, in this example, there are two (2) bleed ducts providing bleed air from the first PSU duct 196A to the IC duct 182 and two (2) bleed ducts providing bleed air from the second PSU duct 196B to the IC duct 182.

In at least one example, the first bleed duct 210A (or first upper bleed duct) provides bleed air from the first PSU duct 196A to the IC duct 182, as described previously. A first lower bleed duct (hidden in FIG. 15) provides bleed air from the first PSU duct 196A to the IC duct 182 (e.g., to a lower portion of the power module heat sink or to a position just below the power module heat sink). In this way, the first lower bleed duct can provide bleed air, which has not passed through the front fin stack 128, to the power module heat sink for cooling the power module, as well as for cooling the lower rear fins of the rear fin stack (hidden in FIG. 15).

In addition, the second bleed duct 210B (or second upper bleed duct) provides bleed air from the second PSU duct 196B to the IC duct 182, as described previously. A second lower bleed duct 266 (an inlet of which is shown in FIG. 15) provides bleed air from the second PSU duct 196B to the IC duct 182 (e.g., to a lower portion of the power module heat sink or to a position just below the power module heat sink). In this way, the second lower bleed duct 266 can provide bleed air, which has not passed through the front fin stack 128, to the power module heat sink for cooling the power module, as well as for cooling the lower rear fins of the rear fin stack. In one or more further examples, more than two (2) bleed ducts can be provided.

In at least one example, the fans 180 of the center cluster associated with the IC duct 182 are controlled independently of the fans 180 of the outer columns, e.g., to control the mass flow rates of the airflows to meet the cooling demands of the IC and other components whilst also minimizing the power usage to drive the fans 180.

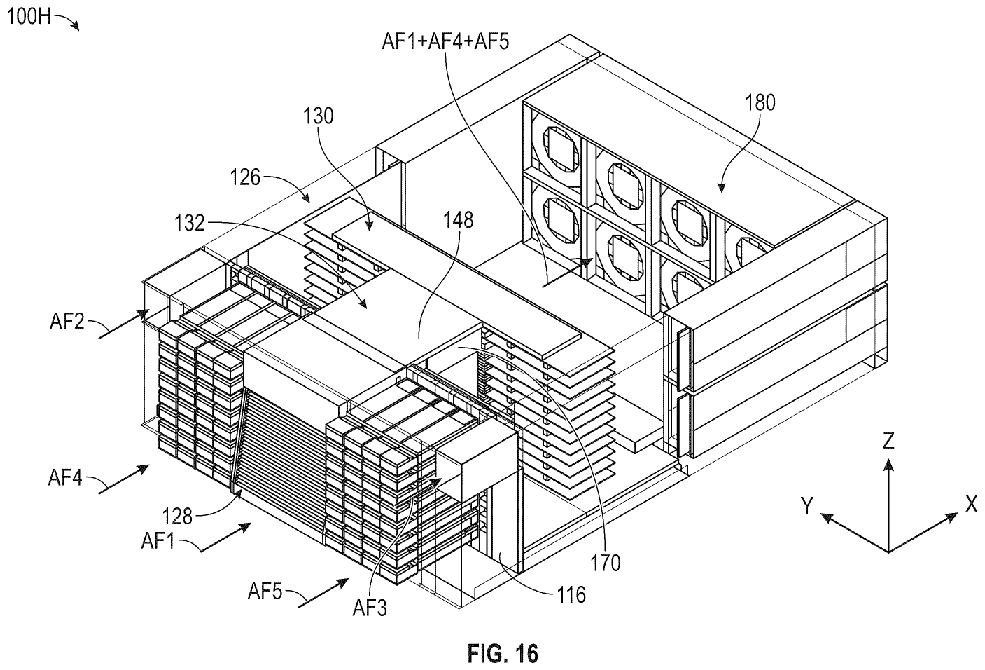

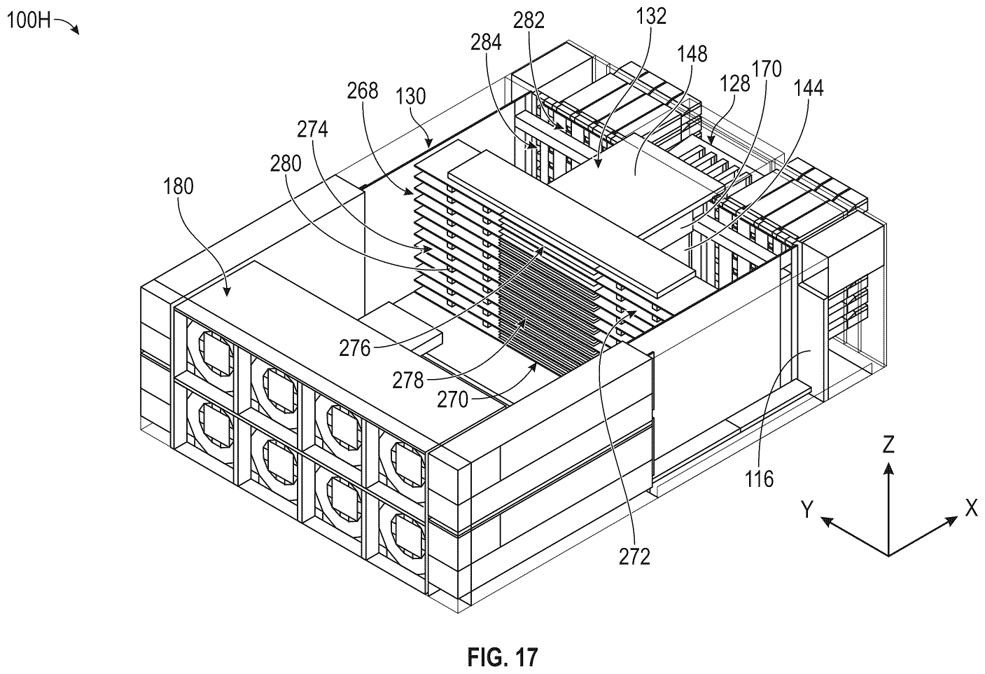

FIGS. 16 and 17 provide perspective views of a VLC system 100H, according to one or more aspects of the present disclosure. FIG. 16 is a front perspective view of the VLC system 100H. FIG. 17 is a rear perspective view of the VLC system 100H. The VLC system 100H is configured in a similar manner as the VLC system 100G of FIG. 15, except as provided below. Accordingly, like numerals will refer to like structures below.

As depicted in FIGS. 16 and 17, the rear fin stack 130 has a rear fin array 268 in addition to the lower rear fins 170 located beneath the horizontal portion 148 of the vapor chamber 132. The rear fin stack 130 does not include upper rear fins, but in other examples, the rear fin stack 130 can include upper rear fins. The rear fin array 268 includes a core 270 and outer sections 272, 274 disposed on both sides of the core 270. The core 270 has a first fin set 276 and a second fin set 278, which each have a plurality of fins. The fins of the first fin set 276 are arranged on top of the second fin set 278. The fins of the first and second fin sets 276, 278 of the core 270 have different vertical spacing between their respective fins. The fins of the first fin set 276 have a first vertical spacing and the fins of the second fin set 278 have a second vertical spacing, which is different than the first vertical spacing. The fins of the first fin set 276 are spaced further apart than are the fins of the second fin set 278. The core 270 has a same or similar lateral width as the width of the power module heat sink 144. Both outer sections 272, 274 have fins as well, which have a third spacing that is different than the spacing of the first and second fin sets 276, 278. Particularly, the fins of the outer sections 272, 274 are spaced vertically further apart than are the fins of the first fin set 276. The fins of the outer sections 272, 274 are also spaced vertically further apart than are the fins of the second fin set 278.

The horizontal portion 148 of the vapor chamber 132 has a T-shape in this example. The T-shaped horizontal portion 148 extends over the lower rear fins 170 and over at least a portion of the rear fin array 268. Rear heat pipes 280 (e.g., cylindrical 3D pipes arranged in a rectangular array) connected to the horizontal portion 148 extend downward through the rear fin array 268, including through the core 270 and outer sections 272, 274.

The fins in-line with the optical cages (i.e., the fins of the outer sections 272, 274) have maximum spacing to maximize optical cage airflow and the fins in the lower central section (the second fin set 278 of the core 270) have minimum vertical spacing to make use of a high velocity jet stemming from the air exiting the lower slot (hidden in FIGS. 16 and 17). Likewise the horizontal fins at the upper region (the fins of the first fin set 276), which are downstream from the lower rear fins 170, have a moderate vertical spacing.

During operation, airflows AF4, AF5 flow through their respective optical connectors and optical cages and pass through the cage holes 282 and drain holes 284 defined by the PCB 116. The airflows AF4, AF5 continue rearward and flow across the fins of the outer sections 272, 274. Airflow AF1 flows through the front fin stack 128 and is directed downward to the lower slot defined by the PCB 116. The airflow AF1 passes through the lower slot and flows upward to carry heat away from the power module heat sink 144 and the lower rear fins 170. The airflow AF1 also flows across the fins of the core 270, including across the fins of the first fin set 276 and the fins of the second fin set 278. Airflows AF1, AF4, and AF5 can combine and flow rearward toward the fans 180. Airflows A2, A3 can flow along their respective PSU ducts to provide cooling to their respective PSUs. In at least one example, bleed air from the PSU ducts can flow along respective bleed ducts to the distributor of the rear fin stack 130. The bleed air can mix with the airflow AF1 to carry heat away from the lower rear fins 170 and the fins of the core 270.

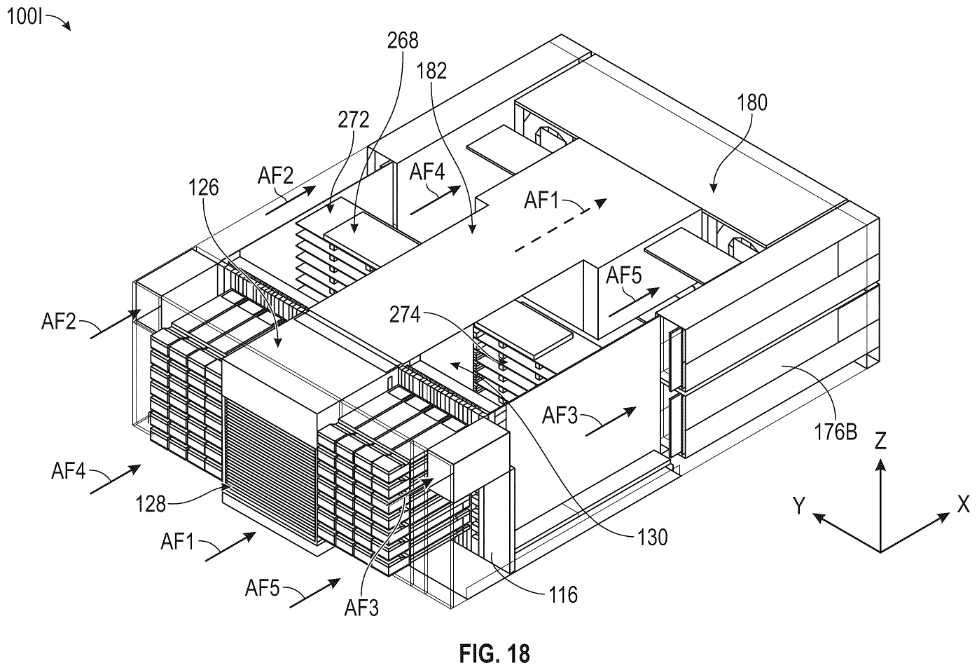

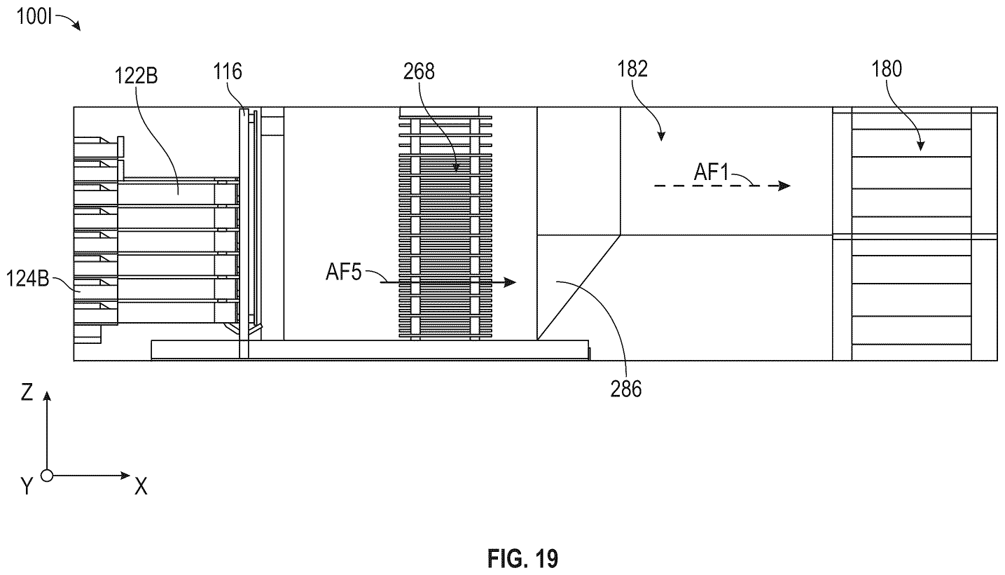

FIGS. 18 and 19 provide perspective views of a VLC system 100I, according to one or more aspects of the present disclosure. FIG. 18 is a front perspective view of the VLC system 100I. FIG. 19 is a side view of the VLC system 100I. The VLC system 100I is configured in a similar manner as the VLC system 100H of FIGS. 16 and 17, except as provided below. Accordingly, like numerals will refer to like structures below.

As illustrated in FIGS. 18 and 19, the IC duct 182 is configured as a central duct (centrally located along the Y-direction of the VLC system 100I) that fluidly isolates the airflow AF1 traveling along the IC duct 182 from the other airflows, except for receiving bleed air from the first and second PSU ducts. Particularly, the airflow AF1 flowing along the IC duct 182 passes through the front fin stack 128 of the IC heat sink 126, through the lower slot defined by the PCB 116, and across the lower rear fins of the rear fin stack 130 as well as the fins of the core 270. Thereafter, the airflow AF1 is directed upward by an IC duct ramp 286 to the two (2) central fans of the top row of the fans 180. The fans 180 move airflows AF4, AF5 through their respective optical connectors cages, through the PCB 116 by way of the cage holes and drain holes, and across their respective outer sections 272, 274. The fans 180 also move airflows AF2, AF3 along their respective PSU ducts to cool their respective PSUs. The fans 180 also move the bleed air from the PSU ducts to the IC duct 182.

In at least one example, the fans 180 associated with the IC duct 182 are controlled independently of the remainder of the fans 180, e.g., to control the mass flow rates of the airflows to meet the cooling demands of the IC and other components whilst also minimizing the power usage to drive the fans 180. The fans 180 can be controlled based on feedback from one or more sensors (e.g., temperature sensors, flow sensors, etc.), e.g., by a computing system of the VLC system. Feedback from the one or more sensors can indicate the heat load of the IC and/or other heat-generating components and the one or more processors can control the fans 180 based at least in part on the heat load.

Accordingly, in the example of FIGS. 18 and 19, the central IC duct 182 encloses the power module heat sink and at least a portion of the rear fin stack and extends to at least one of the plurality of fans 180 (e.g., at least one of the upper fans). The fans 180 associated with the IC duct 182 are arranged to move the airflow AF1, in serial flow, across the front fin stack 128, through the lower slot, across the fins of the power module heat sink, across the core of the rear fin stack 130, and to the fans 180. The IC duct 182 is arranged to separate the AF1 airflow from the airflows AF2, AF3, AF4, AF5 (except for bleed air).

The IC duct 182 can facilitate the IC heat sink 126 extracting the maximum cooling from a limited available airflow. By employing the IC duct 182 to create channelized airflow paths, the IC duct 182 can optimize use of the higher density fins of the core 270 (FIG. 17) without increasing bypass.

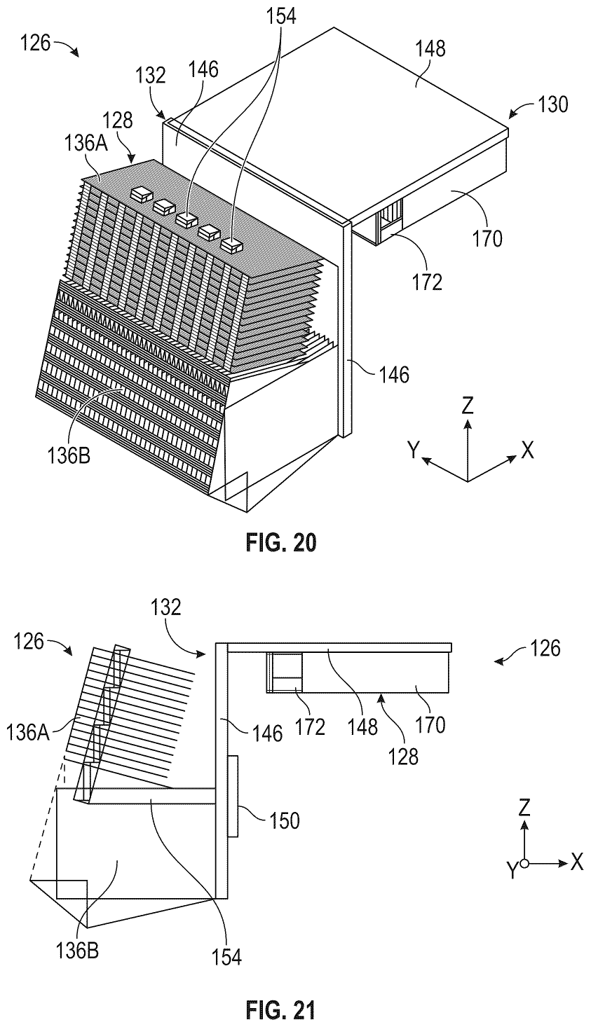

FIGS. 20 and 21 provides views of another example IC heat sink 126 that can be implemented in any one of the VLC systems disclosed herein.

As shown in FIGS. 20 and 21, the IC heat sink 126 has the front fin stack 128, the rear fin stack 130, and the vapor chamber 132. In this example, the front fins of the front fin stack 128 include canted fins 136A and trapezoidal fins 136B. As illustrated in FIGS. 20 and 21, the canted fins 136A and the trapezoidal fins 136B form a stacked arrangement, with the canted fins 136A forming the upper portion of the stack and the trapezoidal fins 136B forming the lower portion of the stack.

The canted fins 136A are arranged with a ninety degree (90°) shift in orientation from the trapezoidal fins 136B, as depicted in FIGS. 20 and 21. The canted fins 136A serve to direct incoming flow downward to the lower slot in the vertically-oriented PCB. The canted fins 136A are canted, or rather, angled with respect to the X-direction. The canted fins 136A can be angled with respect to the X-direction so that the front fin stack 128 “leans rearward”. That is, the canted fins 136A are arranged so that the fins slope downward (e.g., toward a base plate of the chassis) as the canted fins 136A extend rearward along the X-direction. In this way, a lowest end of the canted fins 136A is positioned forward of an uppermost end of the canted fins 136A. The canted fins 136A of the front fin stack 128 are canted at an angle to guide airflow downward to the lower slot, or lower slots, defined at a lower end of a vertically-oriented PCB. The front fin stack 128 can be protected by a sloped housing that extends beyond a forward faceplate of the chassis. Accordingly, in such examples, no perforations or grid is needed.

The heat pipes 154 are fed into the canted fins 136A. The heat pipe orientation can advantageously provide an enhanced gravity-assisted return of condensate to the pedestal 150. In one or more examples, the heat pipes 154 can each be arranged with a bend, e.g., between the vertically-oriented portion and the horizontally-oriented portion of a given heat pipe. In such examples, the bend is defined between seventy and eighty degrees (between 70° and 80°), including the endpoints. The trapezoidal fins 136B attach to the vertical portion 146 of the vapor chamber 132 and can each have a trapezoidal shape with matching slope at the forward face of the front fin stack 128. The slope of the trapezoidal fins 136B at the forward face can match the bend of the heat pipes 154, for example.

In one or more examples, the front fin stack 128 forms the primary EMI shielding at air intake. Fins in the front fin stack can be electrically grounded by a conductive bond to a perimeter housing that is part of a front panel assembly, thus eliminating need for a separate electromagnetic compatibility (EMC) shield panel, which would restrict airflow to the VLC system.

In one or more examples, the front fins of the front fin stack 128 include only canted fins. In one or more examples, the front fins of the front fin stack 128 include only trapezoidal fins.

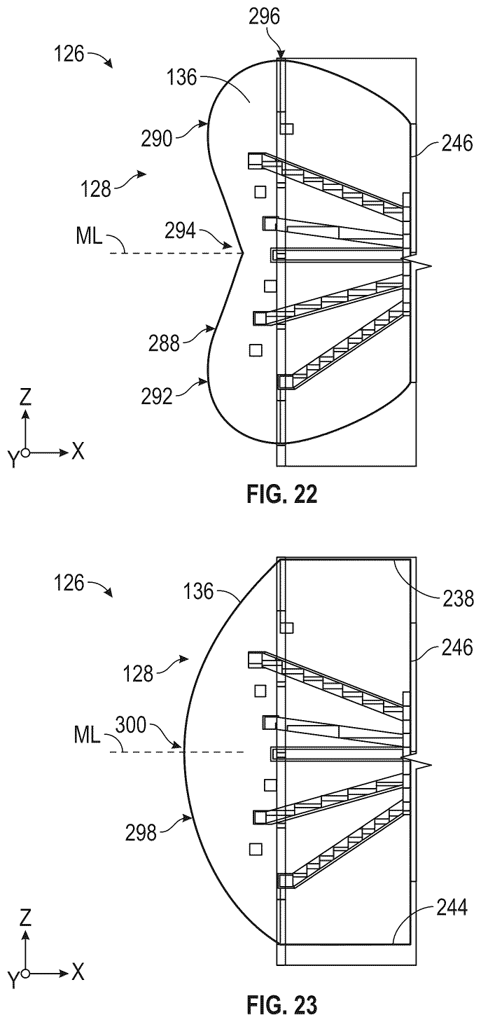

FIG. 22 provides a side profile view of another example IC heat sink 126 that can be implemented in any one of the VLC systems disclosed herein. The IC heat sink 126 of FIG. 22 is configured in a similar manner as the IC heat sink 126 of FIGS. 8 and 9, except as provided below.

In depicted example of FIG. 22, the IC heat sink 126 includes the front fin stack 128, but not a rear fin stack. Moreover, in this example, instead of angled planar faces forming the concave side profile of the front fins 136, the front fins 136 each have a curved face 288, e.g., that extends between an upper end of the rear face 246 and a lower end of the rear face 246. The curvature of the curved face 288 defines an upper forwardmost point 290 of the first half, a lower forwardmost point 292 of the lower half, and a middle inflection point 294 arranged at the vertical midline ML. The upper forwardmost point 290 and the lower forwardmost point 292 are coplanar along the X-direction. The middle inflection point 294 is positioned rearward of both the upper and lower forwardmost points 290, 292 along the X-direction. In this regard, the curvature of the curved face 288 has a sideways truncated heart shape. In at least one example, an uppermost point 296 of the curved face 288 can be arranged at substantially a same height as a chassis top plate of a VLC system along the Z-direction, or stated another way, at a same height as a top edge of a vertically-oriented PCB of the VLC system. In at least one example, the upper forwardmost point 290, the lower forwardmost point 292, and the middle inflection point 294 are arranged forward of a chassis front plate of a VLC system.

In one or more examples, the curved face 288 can extend to the uppermost point 296 and a lowermost point (e.g., both arranged coplanar with a forward plate of the chassis), and the angled rear roof face 238 (FIG. 9) and the angled rear floor face 244 (FIG. 9) can connect the curved face 288 with the rear face 246 at the upper and lower sides of the front fin stack 128, respectively.

FIG. 23 provides a side profile view of another example IC heat sink 126 that can be implemented in any one of the VLC systems disclosed herein. The IC heat sink 126 of FIG. 23 is configured in a similar manner as the IC heat sink 126 of FIGS. 11 and 12, except as provided below.

In illustrated example of FIG. 23, the IC heat sink 126 includes the front fin stack 128, but not a rear fin stack. Moreover, in this example, instead of angled planar faces forming the convex side profile of the front fins 136, the front fins 136 each have a curved face 298, e.g., that extends between a forward end of the rear roof face 238 and a forward end of the rear floor face 244. The curvature of the curved face 298 defines a forwardmost point 300 arranged at the vertical midline ML. The curvature of the curved face 298 provides the front fins 136 with a D-shape. In at least one example, the forwardmost point 300 is positioned forward of a chassis front plate of a VLC system. In one or more other examples, the curved face 298 extends between an upper end of the rear face 246 and a lower end of the rear face 246.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s).

As will be appreciated by one skilled in the art, the subject matter disclosed herein may be embodied as a system, method, or computer program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a computer program product embodied in one or more computer readable medium(s) having computer readable program code embodied thereon.

Program code embodied on a computer readable medium may be transmitted using any appropriate medium, including but not limited to wireless, wireline, optical fiber cable, RF, etc., or any suitable combination of the foregoing.

Computer program code for carrying out operations for embodiments of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described herein with reference to flowchart illustrations and/or block diagrams of methods, apparatuses (systems), and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block(s) of the flowchart illustrations and/or block diagrams.

These computer program instructions may also be stored in a computer readable medium that can direct a computer, other programmable data processing apparatus, or other device to function in a particular manner, such that the instructions stored in the computer readable medium produce an article of manufacture including instructions which implement the function/act specified in the block(s) of the flowchart illustrations and/or block diagrams.

The computer program instructions may also be loaded onto a computer, other programmable data processing apparatus, or other device to cause a series of operational steps to be performed on the computer, other programmable apparatus or other device to produce a computer implemented process such that the instructions which execute on the computer, other programmable data processing apparatus, or other device provide processes for implementing the functions/acts specified in the block(s) of the flowchart illustrations and/or block diagrams.

The flowchart illustrations and block diagrams in the Figures illustrate the architecture, functionality, and operation of possible implementations of systems, methods, and computer program products according to various embodiments. In this regard, each block in the flowchart illustrations or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

In view of the foregoing, the scope of the present disclosure is determined by the claims that follow.

We claim:

1. A vertical line card (VLC) system, comprising:
a vertically-oriented printed circuit board (PCB) defining a lower slot, an upper slot, and a plurality of holes;
a vertically-oriented integrated circuit (IC) mounted to the vertically-oriented PCB;
an IC heat sink having a vapor chamber and a front fin stack positioned forward of the vertically-oriented PCB, the vapor chamber is operable to transfer heat generated by the IC to front fins of the front fin stack;
a cage assembly having cages mounted to the vertically-oriented PCB;
a plurality of fans; and
an IC duct extending at least from the vertically-oriented PCB to at least one fan of the plurality of fans, the at least one fan is operable to move a first portion of an airflow through the upper slot and to the at least one fan, and to move a second portion of the airflow across the front fins, through the lower slot, and to the at least one fan,
wherein the IC duct isolates the airflow from an airflow flowing through the cages and through the plurality of holes to at least one other fan of the plurality of fans.

2. The VLC system of claim 1, wherein the IC heat sink has a rear fin stack positioned rearward of the vertically-oriented PCB and enclosed by the IC duct, and wherein the rear fin stack has rear fins, including upper rear fins positioned above a horizontal portion of the vapor chamber and lower rear fins positioned below the horizontal portion.

3. The VLC system of claim 2, wherein the first portion of the airflow flows across the upper rear fins and the second portion of the airflow flows across the lower rear fins.

4. The VLC system of claim 2, further comprising:
a power supply unit (PSU);
a PSU duct arranged to provide a cooling airflow to the PSU, and wherein the cooling airflow does not pass through the front fin stack; and
a bleed duct arranged to supply bleed air removed from the cooling airflow traveling along the PSU duct to the lower rear fins of the rear fin stack.

5. The VLC system of claim 4, further comprising:
a power module mounted to the vertically-oriented PCB;
a power module heat sink operable to receive heat generated by the power module; and
a lower bleed duct arranged to supply bleed air removed from the cooling airflow traveling along the PSU duct to the power module heat sink.

6. The VLC system of claim 4, wherein the bleed duct is arranged perpendicular to the PSU duct.

7. The VLC system of claim 4, wherein the bleed duct extends through, but is fluidly isolated from, a cage duct defined laterally between the PSU duct and the IC duct, wherein the airflow flowing through the cages and through the plurality of holes to the at least one other fan flows along the cage duct.

8. The VLC system of claim 1, wherein the at least one fan is controllable independently of the at least one other fan.

9. The VLC system of claim 1, wherein the cage assembly is a first cage assembly, and wherein the VLC system further comprises:
a second cage assembly having second cages mounted to the vertically-oriented PCB, wherein the first cage assembly and the second cage assembly are arranged laterally on opposite sides of the vertically-oriented IC, and
wherein the airflow passing through the first cage assembly flows through a first set of the plurality of holes and to a first cage duct and an airflow passing through the second cage assembly flows through a second set of the plurality of holes defined by the vertically-oriented PCB and to a second cage duct, and
wherein the first cage duct and the second cage duct are arranged laterally on opposite sides of the IC duct and are fluidly isolated from the IC duct.

10. The VLC system of claim 9, further comprising:
a first PSU;
a first PSU duct arranged to provide a first cooling airflow to the first PSU, and wherein the first cooling airflow does not pass through the front fin stack;
a second PSU; and
a second PSU duct arranged to provide a second cooling airflow to the second PSU, and wherein the second cooling airflow does not pass through the front fin stack,
wherein the first cage duct is arranged laterally between the IC duct and the first PSU duct and the second cage duct is arranged laterally between the IC duct and the second PSU duct.

11. The VLC system of claim 10, wherein the first cage duct and the second cage duct are fluidly isolated from one another, and wherein fans of a first set of the plurality of fans are operable to move an airflow along the first cage duct and fans of a second set of the plurality of fans are operable to move an airflow along the second cage duct.

12. The VLC system of claim 1, further comprising:
a PSU; and
a PSU duct arranged to provide a cooling airflow to the PSU, and wherein the cooling airflow does not pass through the front fin stack,
wherein at least one of the plurality of fans is stacked on the PSU.

13. The VLC system of claim 1, wherein the IC heat sink has a rear fin stack positioned rearward of the vertically-oriented PCB, and wherein the rear fin stack includes a rear fin array having outer sections disposed on opposite sides of a core of the rear fin array, and wherein the core is enclosed by the IC duct and the outer sections are not enclosed by the IC duct.

14. The VLC system of claim 1, wherein the vertically-oriented PCB defines a corner cutout, and wherein the VLC system further comprises:
a PSU; and
a PSU duct arranged to provide a cooling airflow to the PSU, wherein the PSU duct has an inlet tunnel and a guide ramp, and wherein the inlet tunnel is arranged to guide the cooling airflow through the corner cutout rearward of the vertically-oriented PCB, and the guide ramp is operable to guide the cooling airflow downward to the PSU.

15. A vertical line card (VLC) system, comprising:
a vertically-oriented printed circuit board (PCB) defining a lower slot, an upper slot, and a plurality of holes;
a vertically-oriented integrated circuit (IC) mounted to the vertically-oriented PCB;
an IC heat sink having a front fin stack positioned forward of the vertically-oriented PCB and a rear fin stack positioned rearward of the vertically-oriented PCB;
a cage assembly having cages mounted to the vertically-oriented PCB;
a plurality of fans; and
an IC duct enclosing at least a portion of the rear fin stack and extending at least from the vertically-oriented PCB to at least one fan of the plurality of fans, the at least one fan is operable to move a first portion of an airflow through the upper slot, across rear fins of the rear fin stack, and to the at least one fan, and to move a second portion of the airflow through across front fins of the front fin stack, through the lower slot, across the rear fins of the rear fin stack, and to the at least one fan,
wherein the IC duct isolates the airflow from an airflow flowing through the cages and through the plurality of holes to at least one other fan of the plurality of fans.

16. The VLC system of claim 15, wherein the IC heat sink further includes a vapor chamber having a horizontal portion that extends, at least in part, rearward of the vertically-oriented PCB, and a distributor arranged forward of lower rear fins of the rear fins and below the horizontal portion, and wherein the VLC system further comprises:
a power supply unit (PSU);
a PSU duct arranged to provide a cooling airflow to the PSU, and wherein the cooling airflow does not pass through the front fin stack; and
a bleed duct arranged to supply bleed air removed from the cooling airflow traveling along the PSU duct to the distributor, which distributes the cooling airflow to the lower rear fins.

17. The VLC system of claim 16, wherein the bleed duct has a vertically-oriented segment and a horizontally-oriented segment, with the vertically-oriented segment connected to the PSU duct and the horizontally-oriented segment connected to the rear fin stack.

18. A vertical line card (VLC) system, comprising:
a vertically-oriented printed circuit board (PCB) defining a lower slot and an upper slot;
a vertically-oriented integrated circuit (IC) mounted to the vertically-oriented PCB;
an IC heat sink having a vapor chamber and a front fin stack positioned forward of the vertically-oriented PCB, the vapor chamber is operable to transfer heat generated by the IC to front fins of the front fin stack;
a cage assembly having cages mounted to the vertically-oriented PCB;
a plurality of fans; and
an IC duct having a splitter arranged rearward of the vertically-oriented PCB, the splitter is operable to separate a first portion of an airflow, which moves along the IC duct through the upper slot and to a first set of fans of the plurality of fans, and a second portion of the airflow, which moves along the IC duct across the front fins, through the lower slot, and to a second set of fans of the plurality of fans.

19. The VLC system of claim 18, wherein the first set of fans and the second set of fans are independently controllable.

20. The VLC system of claim 18, further comprising:
a cage assembly having cages mounted to the vertically-oriented PCB,
wherein the IC duct isolates the airflow from an airflow flowing through the cages and through a plurality of holes defined by the vertically-oriented PCB to at least one other fan of the plurality of fans.
